(19) United States
(12) Patent Application Publication
(10) Pub. No.: US 2012/0161284 A1
(43) Pub. Date: Jun. 28, 2012

(54) CHIP RESISTOR AND METHOD FOR MANUFACTURING THE SAME

(75) Inventors: SHEN-CHIH WU, KAOHSIUNG (TW); CHIA-WEN YEH, KAOHSIUNG (TW); CHIH-LUNG CHEN, KAOHSIUNG (TW)

(73) Assignee: YAGEO CORPORATION, Kaohsiung (TW)

(21) Appl. No.: 13/280,675

(22) Filed: Oct. 25, 2011

(30) Foreign Application Priority Data
Dec. 22, 2010 (TW) 099145131

(51) Int. Cl. H01L 29/86; H01L 21/02

(52) U.S. Cl. 257/537; 438/382; 257/E21.004; 257/E29.325

(57) ABSTRACT

The present invention relates to a chip resistor and method for manufacturing the same. The method includes the following steps of: (a) providing a substrate and a resistor layer; (b) attaching the resistor layer to the substrate; (c) forming a first metal layer; (d) forming a plurality of through holes; (e) forming a connecting metal layer in the through holes to electrically connect the resistor layer and the first metal layer; (f) patterning the resistor layer to form a plurality of first resistor bodies; (g) forming a plurality of first protecting layers to protect the first resistor bodies; and (h) proceeding a singulation process along a plurality of cutting lines to form a plurality of chip resistors. Whereby, no alignment problem occurs and the yield can be raised.

### BACKGROUND OF THE INVENTION

1. Field of the Invention

The present invention relates to a chip resistor and a method for manufacturing the same, and more particularly to a chip resistor with a low resistance and a method for manufacturing the same.

2. Description of the Related Art

A chip resistor is a passive element soldered on an integrated circuit to board in an electronic device for providing a resistance value. A conventional chip resistor at least includes a substrate, two front electrodes, two back electrodes, a resistor layer, and two side electrodes.

A manufacturing process of the conventional chip resistor is described as follows. Firstly, a substrate is provided, and the substrate is made of an insulating material which normally is a ceramic substrate, and has a plurality of pre-scribed breaking lines. Then, a plurality of front electrodes is formed on a front side of the substrate, and a plurality of back electrodes is formed on a back side of the substrate. Then, a resistor layer is formed on the front side of the substrate and located in an area between the front electrodes, in which the resistor layer has a predetermined resistance value. Then, the substrate is broken along the breaking lines to form a plurality of single units. Afterwards, two side electrodes are respectively formed on two side surfaces of the single unit to respectively electrically connect the front electrode and the back electrode.

The manufacturing process of the conventional chip resistor has the following drawbacks. As the electronic device becomes dedicated, the size of the conventional chip resistor must be reduced accordingly. When the size of the conventional chip resistor is reduced to a certain range, the front electrodes, the back electrodes, and the resistor layer are difficult to be accurately formed on the single units defined by the breaking lines, and thus the alignment problem occurs and the yield is reduced.

Therefore, it is in need of an innovative and inventive chip resistor and a method for manufacturing the same to solve the above problems.

### SUMMARY OF THE INVENTION

The present invention provides a method for manufacturing a chip resistor, which includes the following steps of: (a) providing a substrate and a resistor layer, in which the substrate has a first surface and a second surface; (b) attaching the resistor layer to the first surface of the substrate; (c) forming a first metal layer on the second surface of the substrate; (d) forming a plurality of through holes to penetrate the first metal layer, the substrate, and the resistor layer; (e) forming a connecting metal layer in the through holes to electrically connect the resistor layer and the first metal layer; (f) patterning the resistor layer to form a plurality of first resistor bodies; (g) forming a plurality of first protecting layers to protect the first resistor bodies; and (h) proceeding a singulation process along a plurality of cutting lines to form a plurality of chip resistors, in which a part of the cutting lines pass through the through holes.

As the substrate is made of a material that can be directly cut, when the size of the chip resistor is reduced to a certain range, the front electrodes, the back electrodes and the resistor layer can be accurately formed on the substrate, and thus, no alignment problem occurs and the yield can be raised.

The present invention also provides a chip resistor, which includes a substrate, a resistor layer, a first metal layer, a connecting metal layer and a first protecting layer. The substrate has a first surface, a second surface, a substrate right opening and a substrate left opening. The resistor layer is located on the first surface of the substrate, and has a first resistor body, a right back electrode and a left back electrode. The right back electrode and the left back electrode are respectively located on two sides of the first resistor body, the right back electrode has a right back electrode opening, and the left back electrode has a left back electrode opening. The first metal layer is located on a second surface of the substrate and has a first right opening and a first left opening, in which the substrate right opening, the right back electrode opening and the first right opening form a right penetrating groove, and the substrate left opening, the left back electrode opening and the first left opening form a left penetrating groove. The connecting metal layer includes a connecting metal right part and a connecting metal left part, in which the connecting metal right part and the connecting metal left part are not connected, the connecting metal right part is located in the right penetrating groove and electrically connects the right back electrode and the first metal layer, and the connecting metal left part is located in the left penetrating groove and electrically connects the left back electrode and the first metal layer. The first protecting layer covers the first resistor body.

### BRIEF DESCRIPTION OF THE DRAWINGS

The invention will be described according to the appended drawings in which:

FIG. 1 to FIG. 13 are schematic views of a method for manufacturing a chip resistor according to a first embodiment of the present invention;

FIG. 14 is a schematic cross-sectional view of a chip resistor according to the first embodiment of the present invention;

FIG. 15 to FIG. 27 are schematic views of a method for manufacturing a chip resistor according to a second embodiment of the present invention; and

FIG. 28 is a schematic cross-sectional view of a chip resistor according to the second embodiment of the present invention.

### DETAILED DESCRIPTION OF THE INVENTION

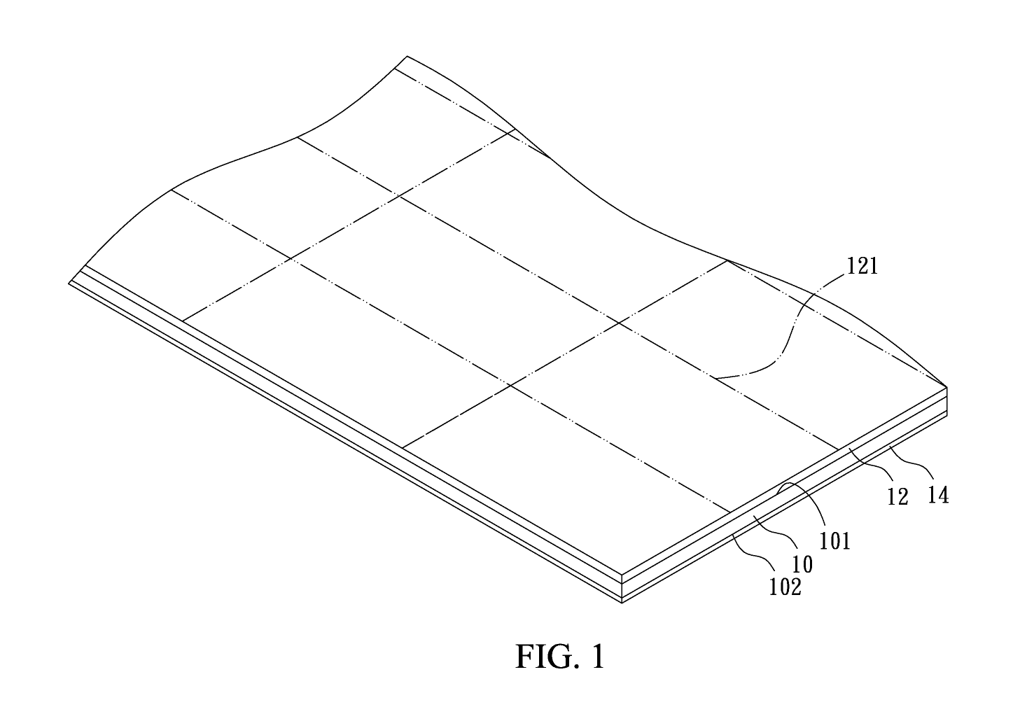

FIG. 1 to FIG. 13 are schematic views of a method for manufacturing a chip resistor according to a first embodiment of the present invention. Referring to FIG. 1, a substrate 10 and a resistor layer 12 are provided. The substrate 10 has a first surface 101 and a second surface 102. Then, the resistor layer 12 is attached to the first surface 101 of the substrate 10. Then, a first metal layer 14 is formed on the second surface 102 of the substrate 10.

In this embodiment, the substrate 10 is an organic substrate, and preferably is an organic laminate substrate. The resistor layer 12 is a Cu—Ni alloy foil or a Cu—Mn alloy foil. The first metal layer 14 is a Cu foil. Since the resistor layer 12 is a sheet material, the resistor layer 12 is attached to the first surface 101 of the substrate 10 by lamination, and preferably, an adhesive layer (not shown) is further formed between the resistor layer 12 and the substrate 10. Furthermore, the first metal layer 14 is also a sheet material, and is formed on the second surface 102 of the substrate 10 by lamination, and preferably, an adhesive layer (not shown) is further formed between the first metal layer 14 and the substrate 10.

In this embodiment, a surface of the resistor layer 12 has a plurality of predetermined cutting lines 121. Since the cutting lines 121 are imaginary, the cutting lines 121 are indicated by imaginary lines in the figure. It should be understood that the cutting lines 121 may also be physical cutting lines located on the substrate 10, for example, breaking lines.

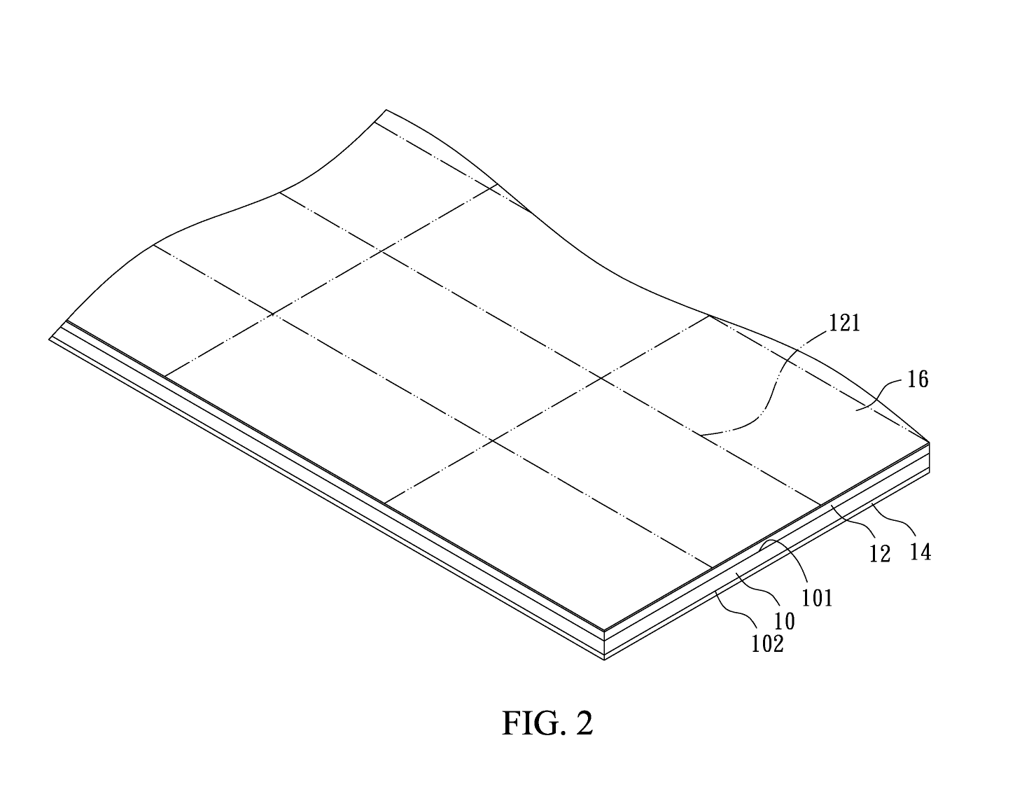

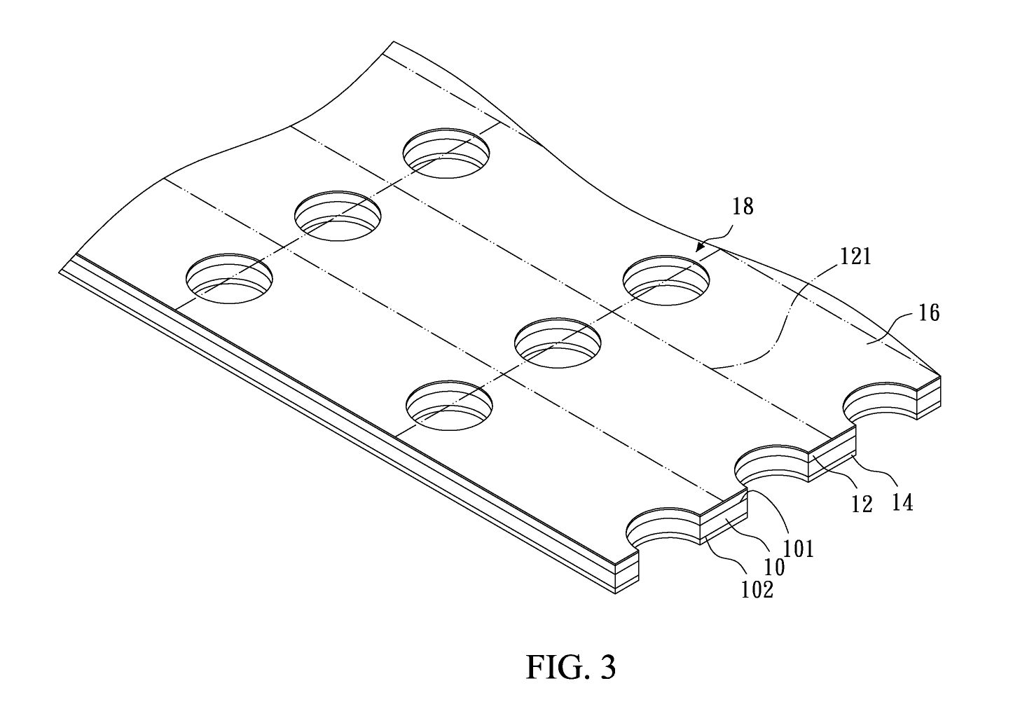

Referring to FIG. 2, an adhesive layer 16 (for example, a first photoresist layer or a protective adhesive) is formed to cover the resistor layer 12. Referring to FIG. 3, a plurality of through holes 18 are formed to penetrate the first metal layer 14, the substrate 10, the resistor layer 12 and the adhesive layer 16. The through holes 18 are located on the cutting lines 121 but are not located at intersections of the cutting lines 121.

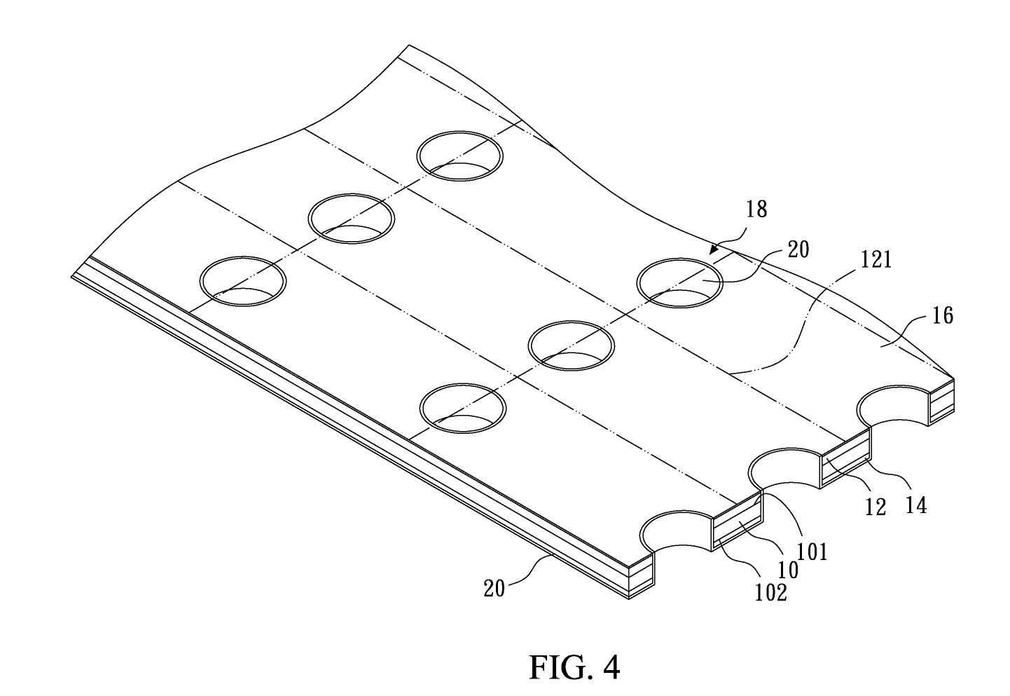

Referring to FIG. 4, a connecting metal layer 20 is formed in the through holes 18 to electrically connect the resistor layer 12 and the first metal layer 14. In this embodiment, the connecting metal layer 20 is a chemical metal layer, for example, a chemical Cu layer, and is formed by a chemical plating process. Furthermore, the connecting metal layer 20 is further formed on the entire plane of the first metal layer 14.

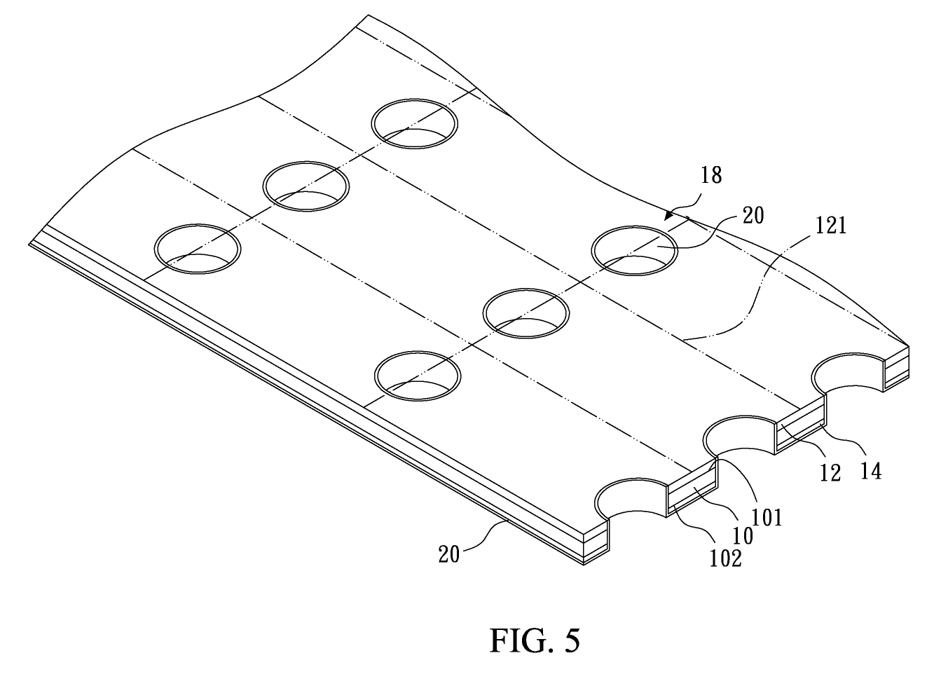

Referring to FIG. 5, the adhesive layer 16 is removed to expose the entire resistor layer 12.

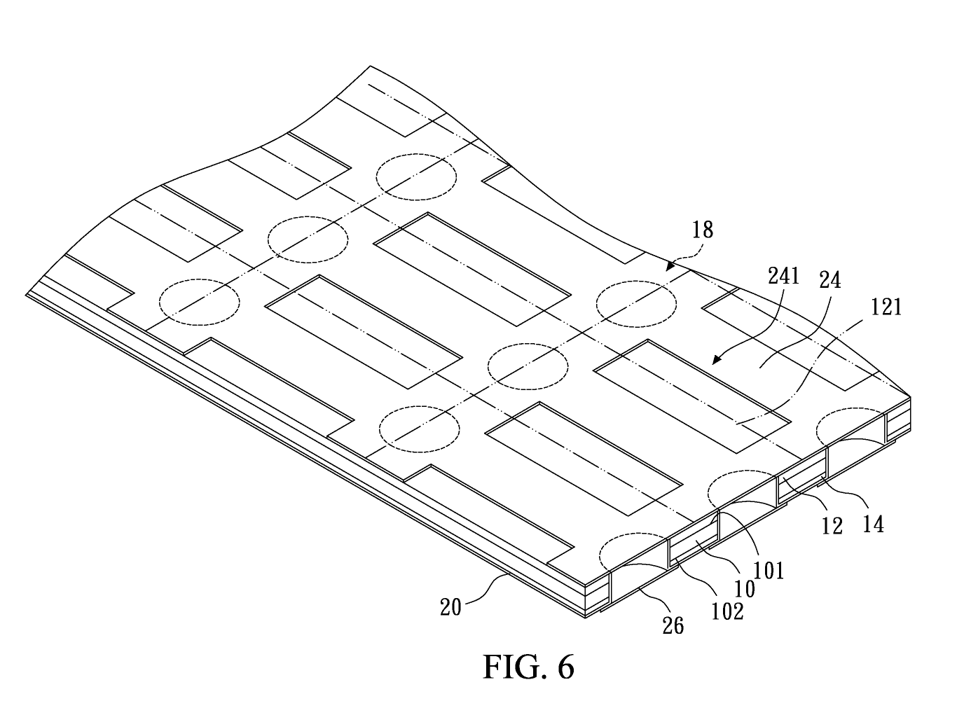

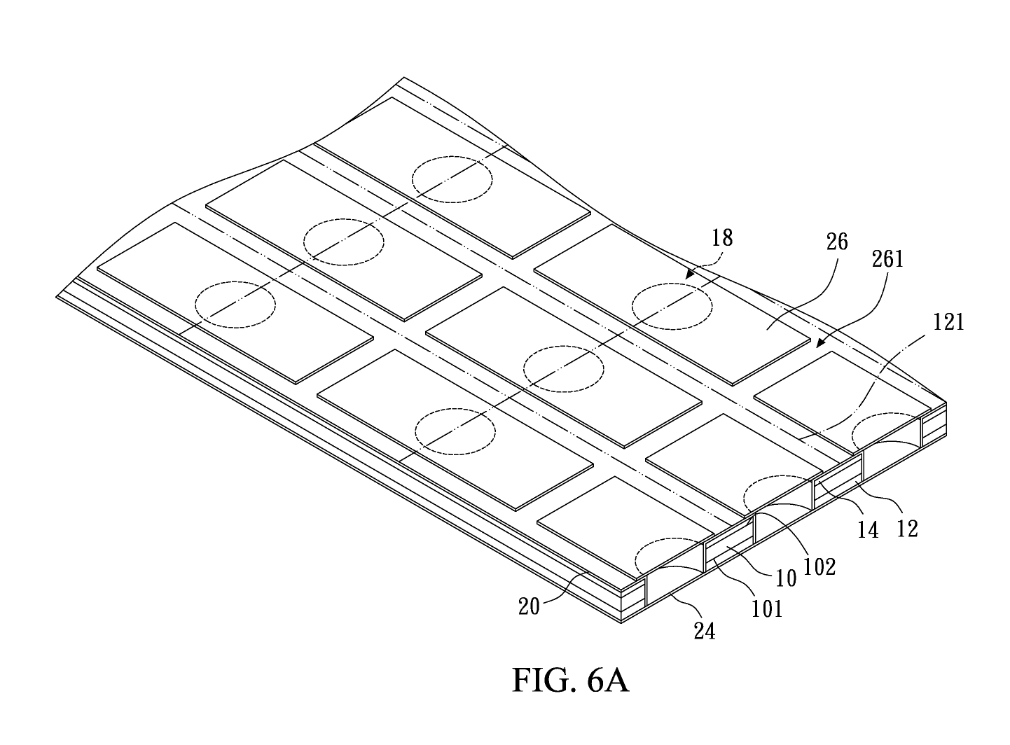

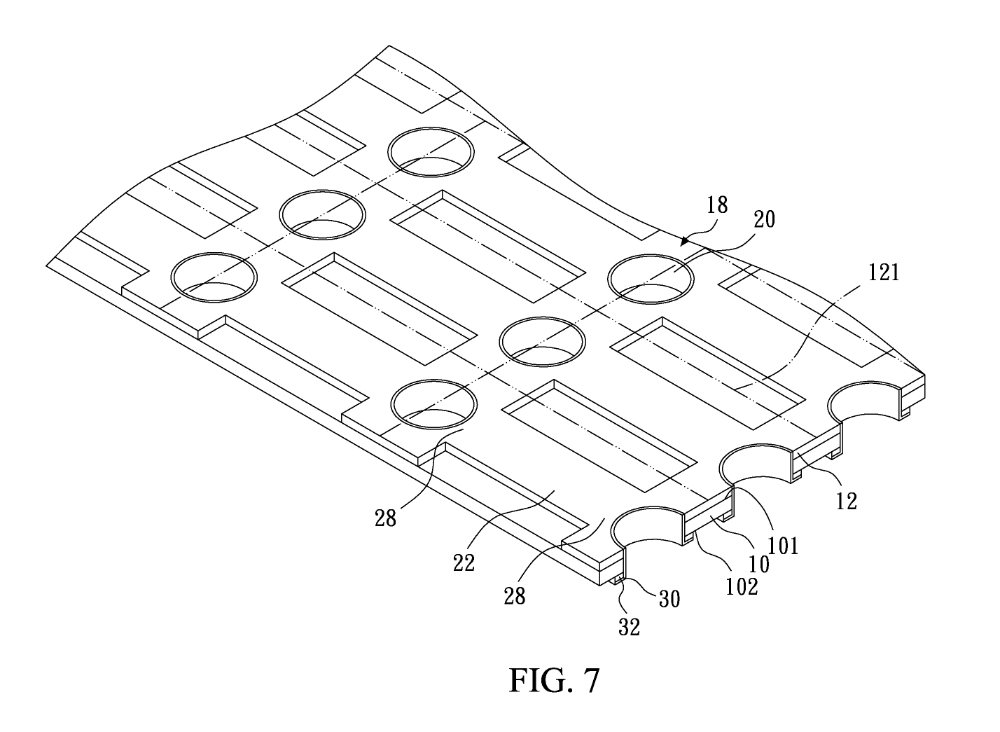

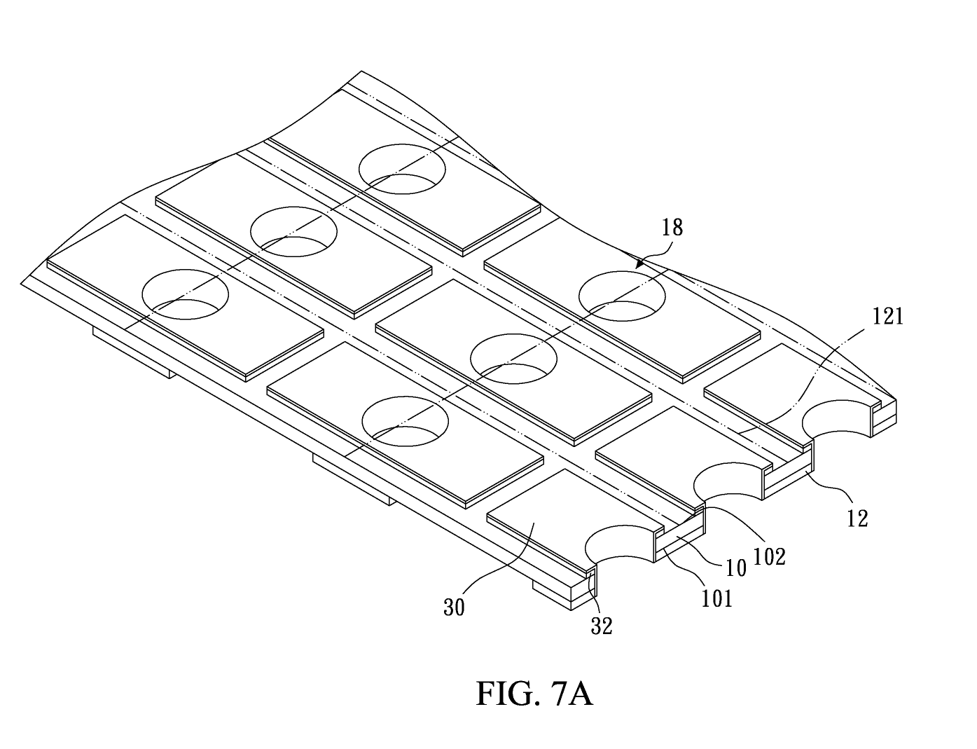

Referring to FIG. 6, FIG. 6A, FIG. 7, and FIG. 7A, wherein FIG. 6A is a perspective bottom view of FIG. 6, and FIG. 7A is a perspective bottom view of FIG. 7. The resistor layer 12 is patterned to form a plurality of first resistor bodies 22. In this embodiment, the patterning process is described as follows. Firstly, referring to FIG. 6 and FIG. 6A, a second photoresist layer 24 is formed on the resistor layer 12, and a third photoresist layer 26 is formed on the connecting metal layer 20. Then, after exposure and development, a second pattern 241 is formed on the second photoresist layer 24, and a third pattern 261 is formed on the third photoresist layer 26. The second pattern 241 is a plurality of openings, and the third pattern 261 is a plurality of crossed grooves. The positions of the openings and the grooves do not correspond to the through holes 18. That is, the openings and the grooves do not pass through the through holes 18.

Then, referring to FIG. 7 and FIG. 7A, a part of the resistor layer 12 is removed by etching according to the second pattern 241 to expose a part of the first surface 101 of the substrate 10, and a plurality of first resistor bodies 22 and a plurality of back electrodes 28 are formed. Every two back electrodes 28 are located on two sides of each first resistor body 22, and the position of each back electrode 28 corresponds to one through holes 18. A part of the connecting metal layer 20 and the first metal layer 14 are removed according to the third pattern 261 by etching to expose a part of the second surface 102 of the substrate 10, and a plurality of heat dissipation mechanisms 30 and a plurality of front electrodes 32 are respectively formed. The heat dissipation mechanisms 30 are located on the front electrodes 32, and the front electrodes 32 are spaced apart to each other. Each front electrode 32 includes one through hole 18. Afterwards, the second photoresist layer 24 and the third photoresist layer 26 are removed.

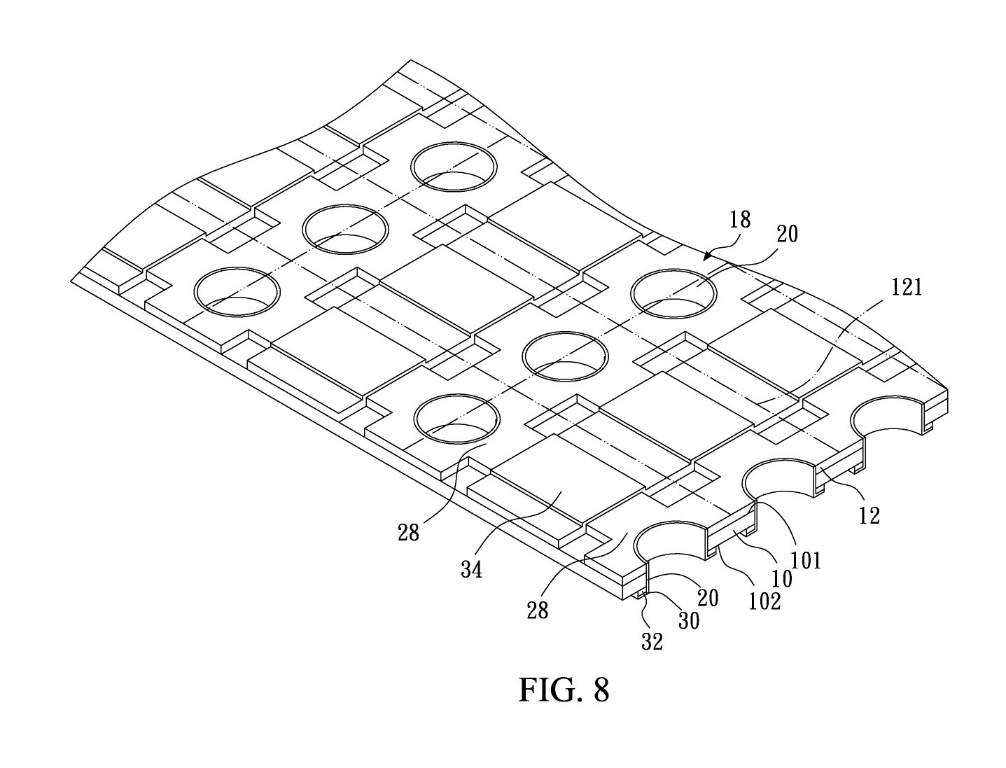

Referring to FIG. 8, a plurality of first non-conductive material layers 34 are formed to cover the first resistor bodies 22 and a part of the first surface 101 of the substrate 10. The first non-conductive material layers 34 are parallel to each other and do not cover the through holes 18. In this embodiment, the first non-conductive material layer 34 is a dry film or a wet film.

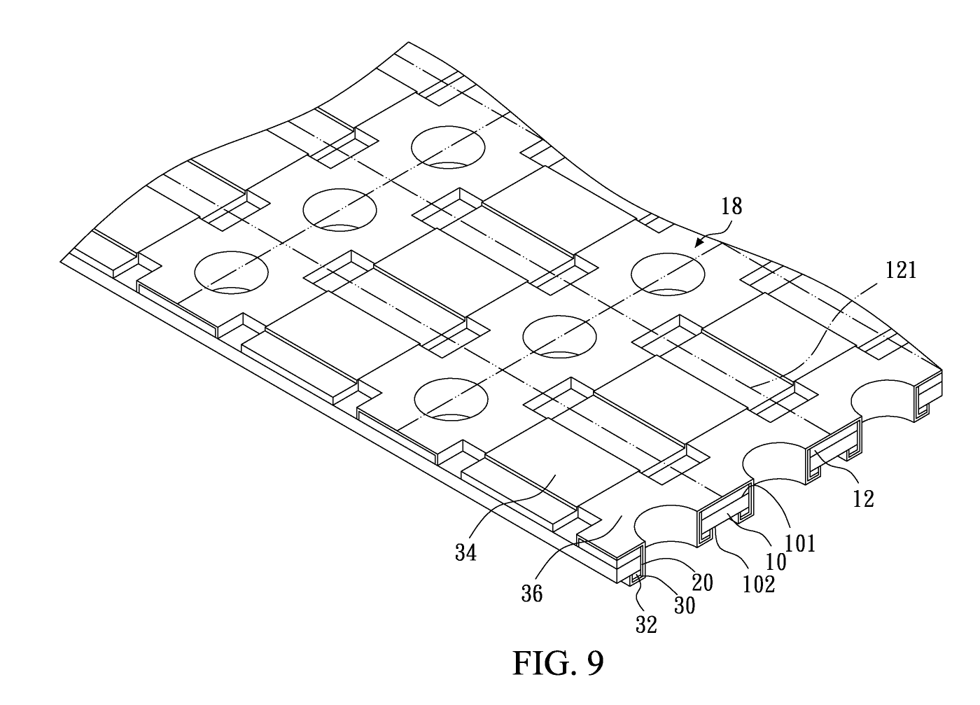

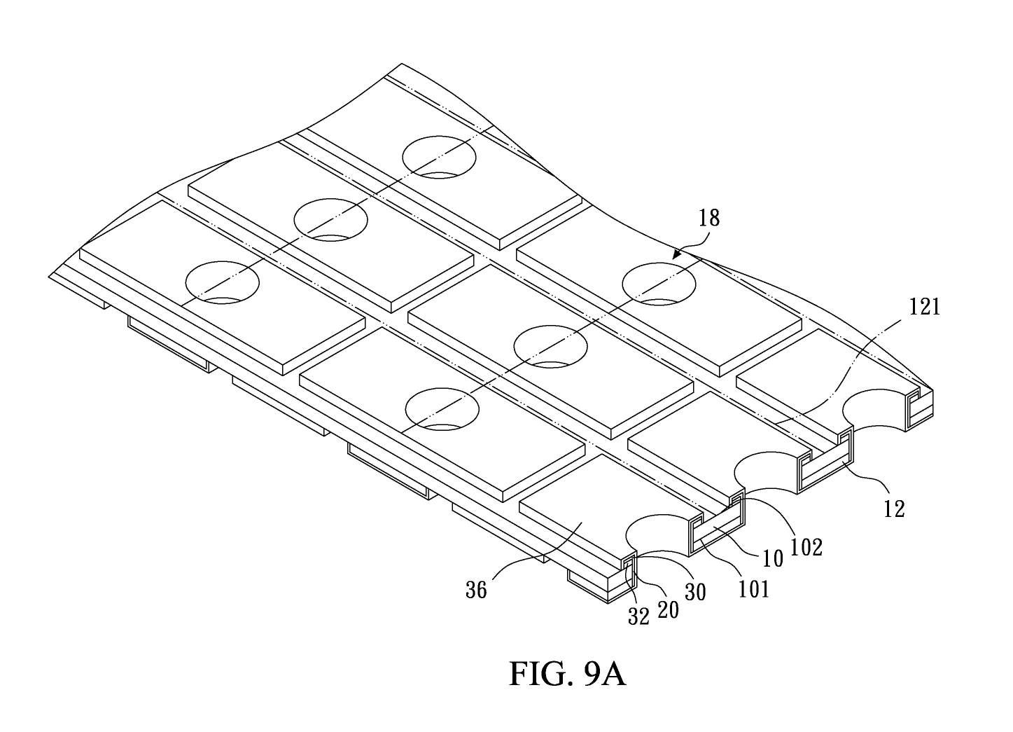

Referring to FIG. 9 and FIG. 9A, wherein FIG. 9A is a perspective bottom view of FIG. 9. A plurality of second metal layers 36 are formed on a part of the resistor layer 12 that is not covered by the first non-conductive material layers 34 (that is, the back electrodes 28) and the connecting metal layer 20 (that is, the through holes 18 and the heat dissipation mechanisms 30). In this embodiment, the second metal layer 36 is a Cu layer and is formed by electroplating. The second metal layer 36 extends to a side edge of the back electrodes 28 and contacts the first surface 101 of the substrate 10. Further, the second metal layer 36 extends to the heat dissipation mechanisms 30 and the side edges of the front electrodes 32 and contacts the second surface 102 of the substrate 10.

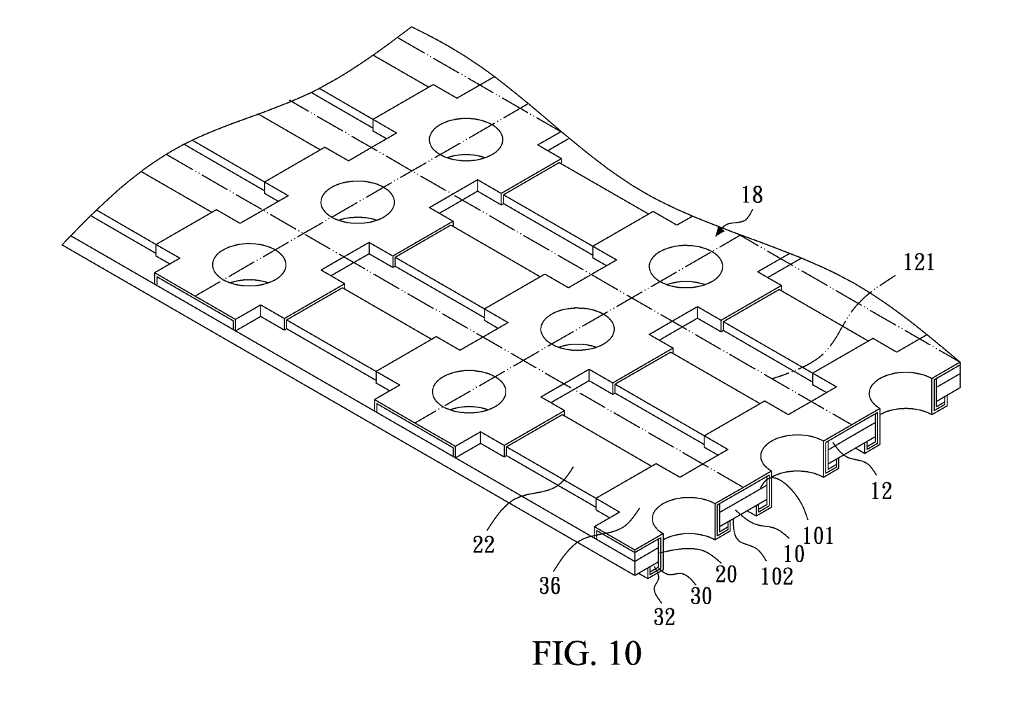

Referring to FIG. 10, the first non-conductive material layers 34 are removed to expose the first resistor bodies 22 and a part of the first surface 101 of the substrate 10.

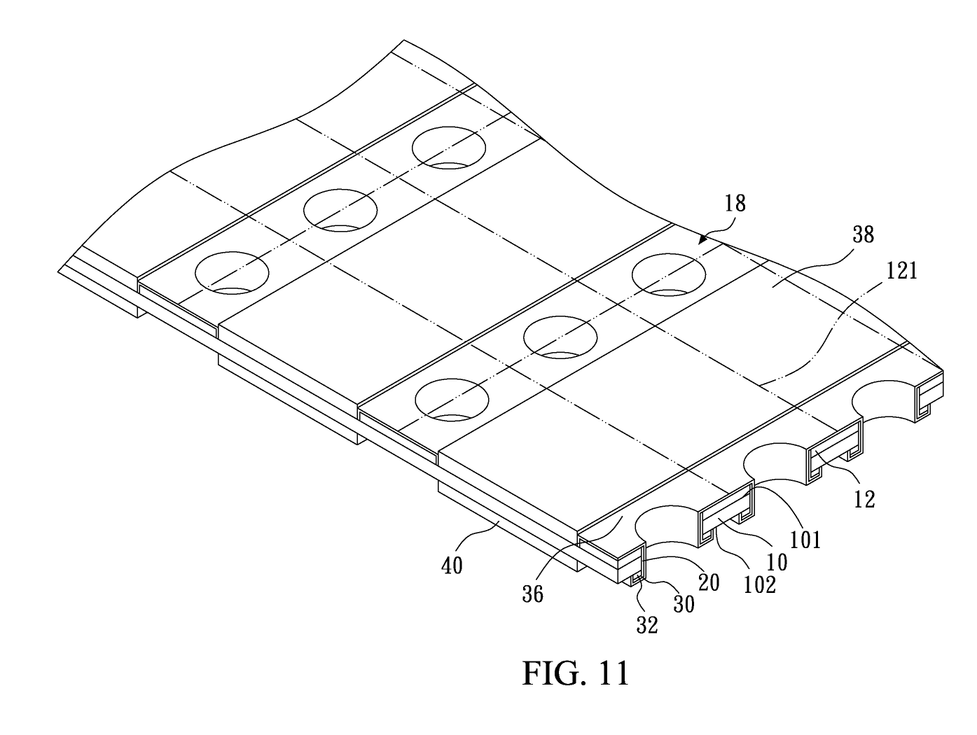

Referring to FIG. 11, a plurality of first protecting layers 38 are formed to protect the first resistor bodies 22. In this embodiment, the material of the first protecting layers 38 is a solder resist ink, such as epoxy. The first protecting layers 38 cover the first resistor bodies 22 and a part of the first surface 101 of the substrate 10. The first protecting layers 38 do not cover the through holes 18.

Preferably, in this embodiment, a plurality of second protecting layers 40 are further formed to cover a part of the second metal layers 36 and a part of the second surface 102 of the substrate 10. The second protecting layers 40 do not cover the through holes 18. In this embodiment, the material of the second protecting layers 40 is a solder resist ink, such as epoxy.

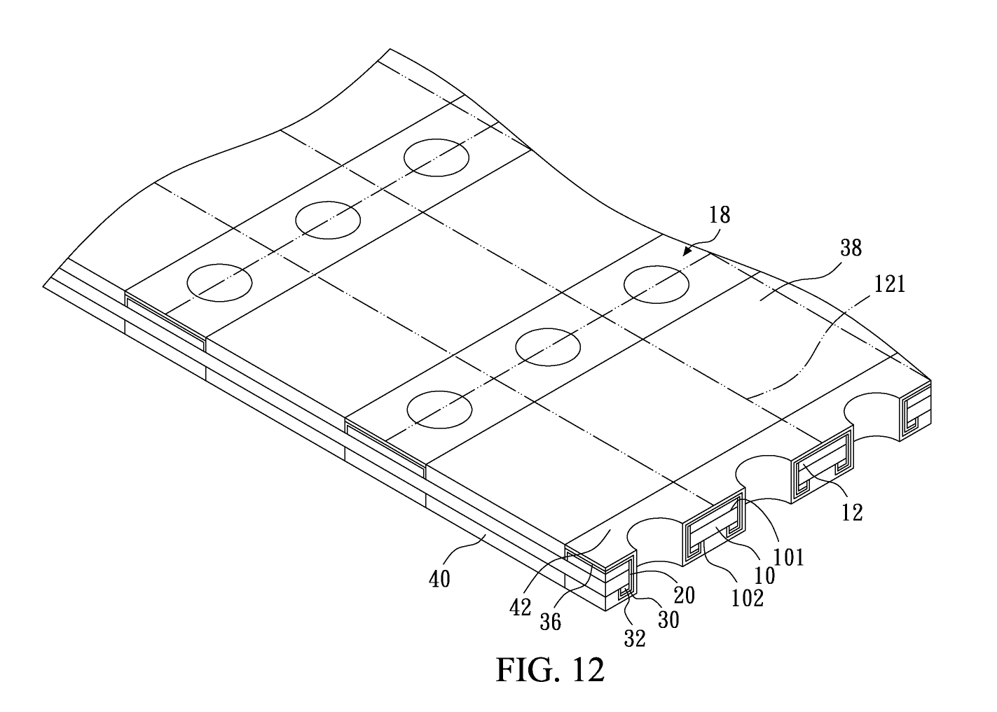

Referring to FIG. 12, a plurality of third metal layers 42 are formed on a part of the second metal layer 36 that is not covered by the first protecting layers 38 and the second protecting layers 40. In this embodiment, the third metal layer 42 is formed by electroplating, and the material is Ni, Sn, or Au. Preferably, if the material of the third metal layer 42 is Ni, an Au or Sn layer may be further electroplated thereon. In other embodiments, the third metal layer 42 fills up the through holes 18.

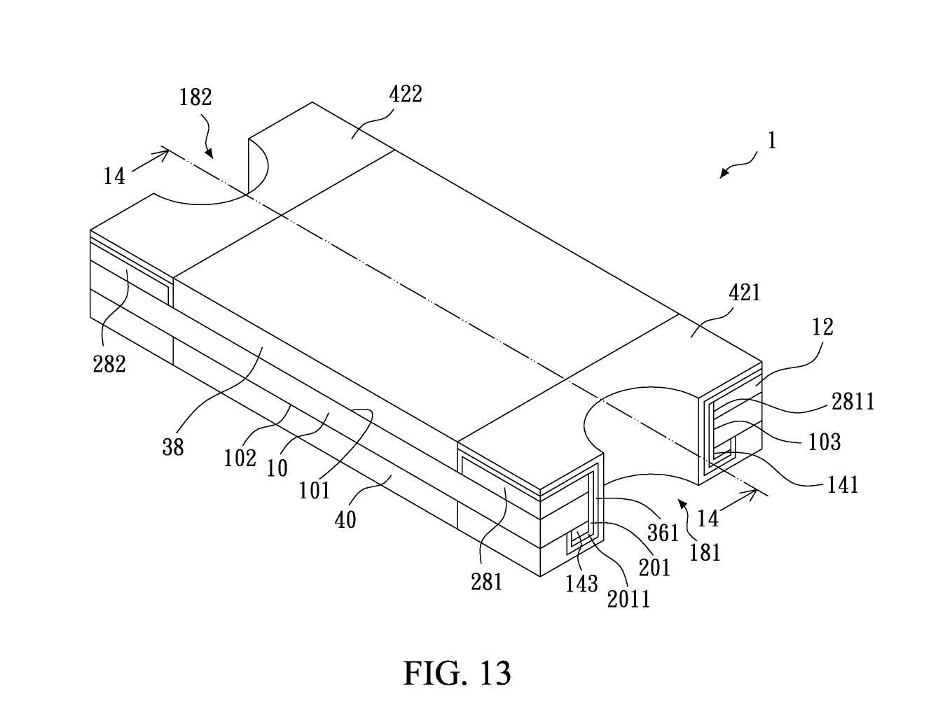

Finally, a singulation process is proceeded along the cutting lines 121 to form a plurality of chip resistors 1 as shown in FIG. 13. A part of the cutting lines 121 pass through the through holes 18. In this embodiment, the singulation process uses a laser or a cutter to proceed cutting along the cutting lines 121. However, it should be understood that if the cutting lines 121 are physical breaking lines located on the substrate 10, the singulation process uses a breaking machine to proceed the breaking process along the cutting lines 121.

In the present invention, the substrate 10 is a material that can be directly cut, so when the size of the chip resistor 1 is reduced to a certain range, the front electrodes 32, the back electrodes 28 and the resistor layers 22 can be accurately formed on the substrate 10. Therefore, no alignment problem occurs and the yield can be raised.

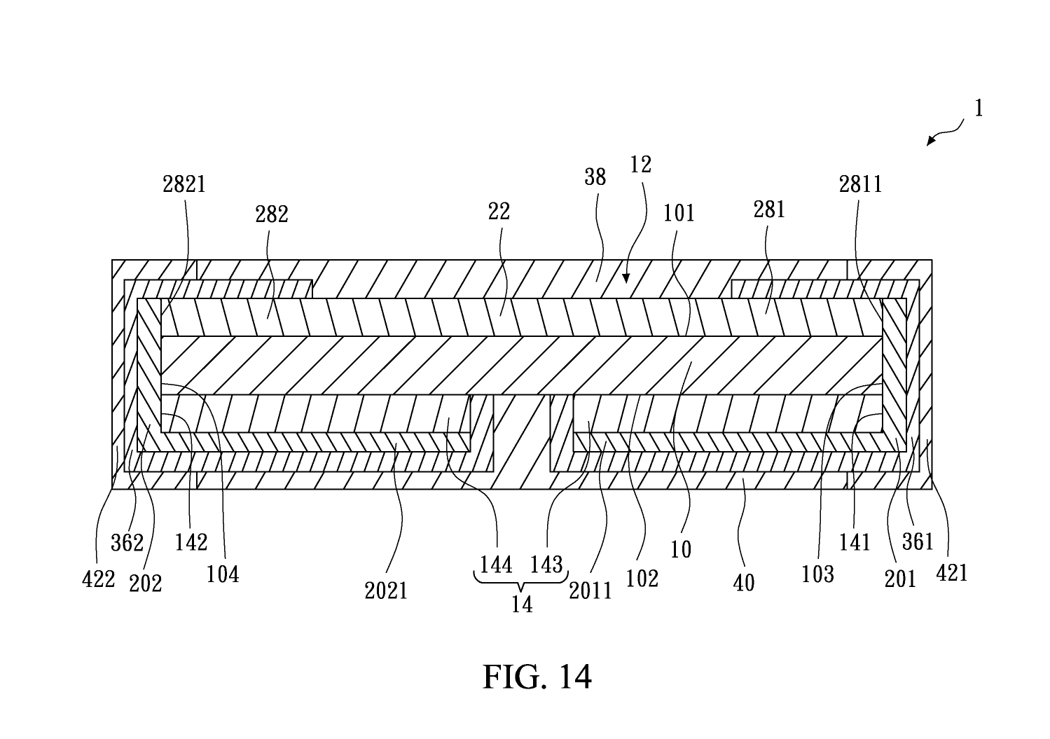

FIG. 13 and FIG. 14 are schematic perspective and cross-sectional views of a chip resistor according to the first embodiment of the present invention respectively. The chip resistor 1 includes a substrate 10, a resistor layer 12, a first metal layer 14, a connecting metal layer and a first protecting layer 38.

The substrate 10 has a first surface 101, a second surface 102, a substrate right opening 103 and a substrate left opening 104. In this embodiment, the substrate 10 is an organic substrate, and preferably is an organic laminate substrate.

The resistor layer 12 is located on the first surface 101 of the substrate 10, and has a first resistor body 22, a right back electrode 281 and a left back electrode 282. The right back electrode 281 and the left back electrode 282 are respectively located on two sides of the first resistor bodies 22. The right back electrode 281 has a right back electrode opening 2811, and the left back electrode 282 has a left back electrode opening 2821. In this embodiment, the resistor layer 12 is a Cu—Ni alloy foil or a Cu—Mn alloy foil. Preferably, an adhesive layer (not shown) is further formed between the resistor layer 12 and the substrate 10.

The first metal layer 14 is located on the second surface 102 of the substrate 10, and has a first right opening 141 and a first left opening 142. The substrate right opening 103, the right back electrode opening 2811 and the first right opening 141 form a right penetrating groove 181, and the substrate left opening 104, the left back electrode opening 2821 and the first left opening 142 form a left penetrating groove 182. In this embodiment, the first metal layer 14 is a Cu foil. Preferably, an adhesive layer (not shown) is further formed between the first metal layer 14 and the substrate 10. The first metal layer 14 includes a right front electrode 143 and a left front electrode 144. The right front electrode 143 and the left front electrode 144 are not connected, and are separated by a clearance.

The right front electrode 143 and the left front electrode 144 are formed from the front electrodes 32 (FIG. 7 and FIG. 7A) after the singulation process.

The connecting metal layer includes a connecting metal right part 201 and a connecting metal left part 202. The connecting metal right part 201 and the connecting metal left part 202 are not connected, and the connecting metal right part 201 is located in the right penetrating groove 181 and electrically connects the right back electrode 281 and the right front electrode 143 of the first metal layer 14. The connecting metal left part 202 is located in the left penetrating groove 182 and electrically connects the left back electrode 282 and the left front electrode 144 of the first metal layer 14. In this embodiment, the connecting metal layer is a chemical metal layer, such as a chemical Cu layer. The connecting metal right part 201 and the connecting metal left part 202 are formed from the connecting metal layer 20 (FIG. 12) after the singulation process.

The connecting metal right part 201 includes a right heat dissipation mechanism 2011 located on the right front electrode 143. The connecting metal left part 202 includes a left heat dissipation mechanism 2021 located on the left front electrode 144. The right heat dissipation mechanism 2011 and the left heat dissipation mechanism 2021 are formed from the heat dissipation mechanisms 30 (FIG. 7 and FIG. 7A) after the singulation process.

The first protecting layers 38 cover the first resistor bodies 22. In this embodiment, the material of the first protecting layers 38 is solder resist ink, such as epoxy. The first protecting layers 38 cover the first resistor bodies 22 and a part of the first surface 101 of the substrate 10.

Preferably, the chip resistor 1 further includes a second metal layer right part 361, a second metal layer left part 362, a second protecting layer 40, a third metal layer right part 421 and a third metal layer left part 422.

The material of the second metal layer right part 361 and the second metal layer left part 362 is Cu. The second metal layer right part 361 is located on the connecting metal right part 201, and the second metal layer right part 361 extends to a side edge of the right back electrode 281 and contacts the first surface 101 of the substrate 10. The second metal layer right part 361 extends to the right heat dissipation mechanism 2011 and a side edge of the right front electrode 143, and contacts the second surface 102 of the substrate 10.

The second metal layer left part 362 is located on the connecting metal left part 202, and the second metal layer left part 362 extends to a side edge of the left back electrode 282 and contacts the first surface 101 of the substrate 10. The second metal layer left part 362 extends to the left heat dissipation mechanism 2021 and a side edge of the left front electrode 144, and contacts the second surface 102 of the substrate 10.

The second protecting layer 40 is located on the second surface 102 of the substrate 10 between the right front electrode 143 and the left front electrode 144 to cover a part of the second metal layers 36 (the second metal layer right part 361 and the second metal layer left part 362) and a part of the second surface 102 of the substrate 10. In this embodiment, the material of the second protecting layers 40 is the solder resist ink, such as epoxy.

The third metal layer right part 421 is located on the second metal layer right part 361, and the third metal layer left part 422 is located on the second metal layer left part 362. In this embodiment, the material of the third metal layer right part 421 and the third metal layer left part 422 is Ni, Sn, or Au. Preferably, if the material of the third metal layer right part 421 and the third metal layer left part 422 is Ni, an Au or Sn layer may be further electroplated thereon.

In this embodiment, the chip resistor 1 has two penetrating grooves (that is, the right penetrating groove 181 and the left penetrating groove 182). However, in other embodiments, the chip resistor 1 may have more than four penetrating grooves, that is, one side has more than two penetrating grooves. The penetrating grooves on the same side may be conducted or not conducted.

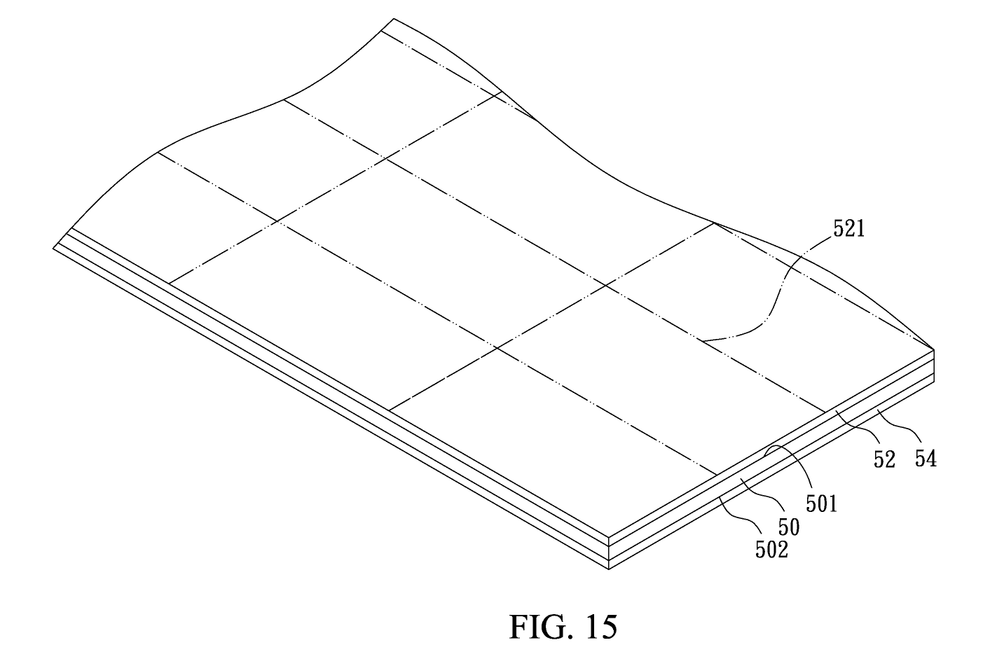

FIG. 15 to FIG. 27 are schematic views of a method for manufacturing a chip resistor according to a second embodiment of the present invention. Referring to FIG. 15, a substrate 50 and a resistor layer 52 are provided. The substrate 50 has a first surface 501 and a second surface 502. Then, the resistor layer 52 is attached to the first surface 501 of the substrate 50. Then, a first metal layer 54 is formed on the second surface 502 of the substrate 50.

In this embodiment, the substrate 50 is an organic substrate, and preferably is an organic laminate substrate. The resistor layer 52 is a Cu—Ni alloy foil or a Cu—Mn alloy foil. The first metal layer 54 is also a Cu—Ni alloy foil or a Cu—Mn alloy foil. Since the resistor layer 52 is a sheet material, the resistor layer 52 is attached to the first surface 501 of the substrate 50 by lamination. Preferably, an adhesive layer (not shown) is further formed between the resistor layer 52 and the substrate 50. Furthermore, the first metal layer 54 is also a sheet material and is formed on the second surface 502 of the substrate 50 by lamination. Preferably, an adhesive layer (not shown) is further formed between the first metal layer 54 and the substrate 50.

In this embodiment, a surface of the resistor layer 52 has a plurality of predetermined cutting lines 521.

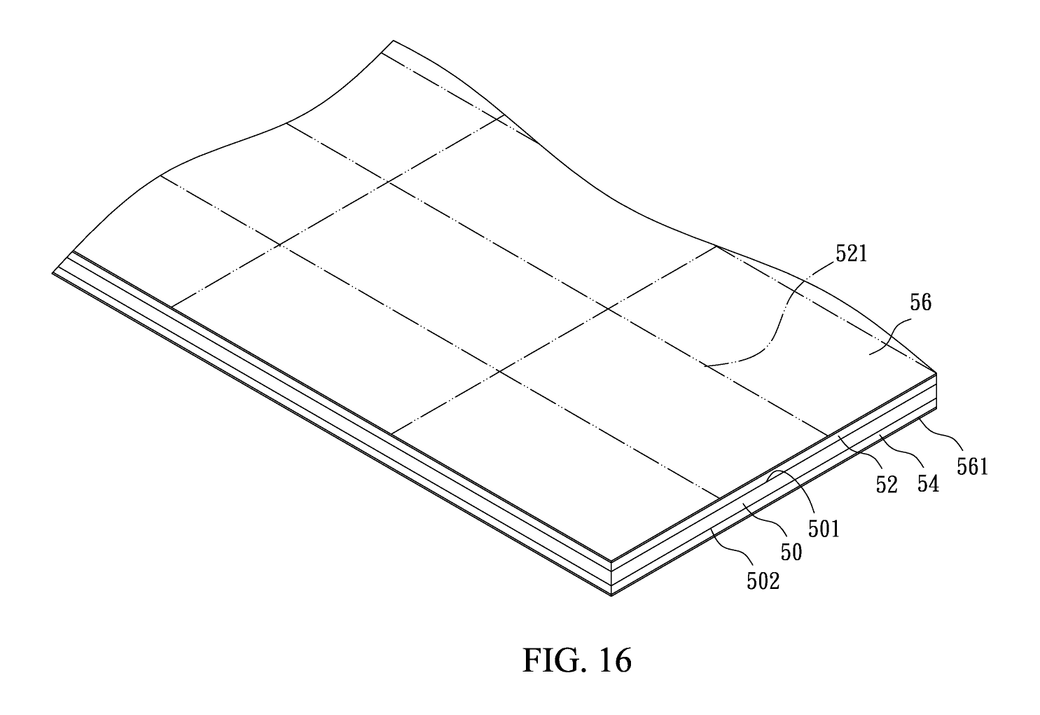

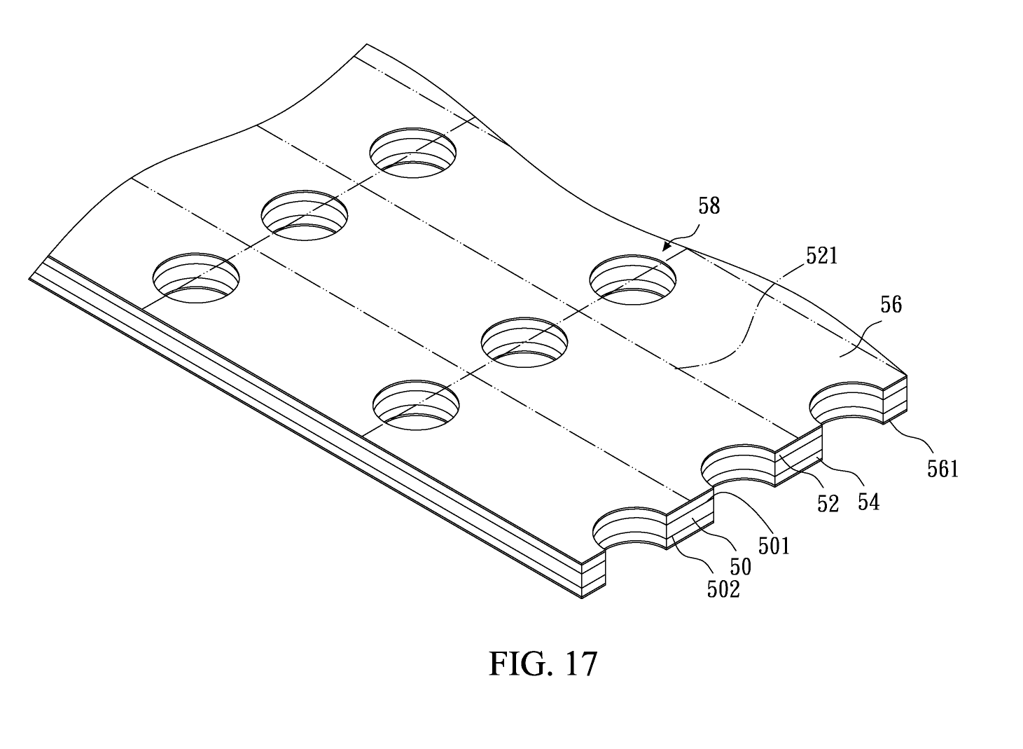

Referring to FIG. 16, an adhesive layer 56 (for example, a first photoresist layer or a protective adhesive) is formed to cover the resistor layer 52, and a second photoresist layer 561 is formed to cover the first metal layer 54. Referring to FIG. 17, a plurality of through holes 58 are formed to penetrate the second photoresist layer 561, the first metal layer 54, the substrate 50, the resistor layer 52 and the adhesive layer 56. The through holes 58 are located on the cutting lines 521 but are not located at intersections of the cutting lines 521.

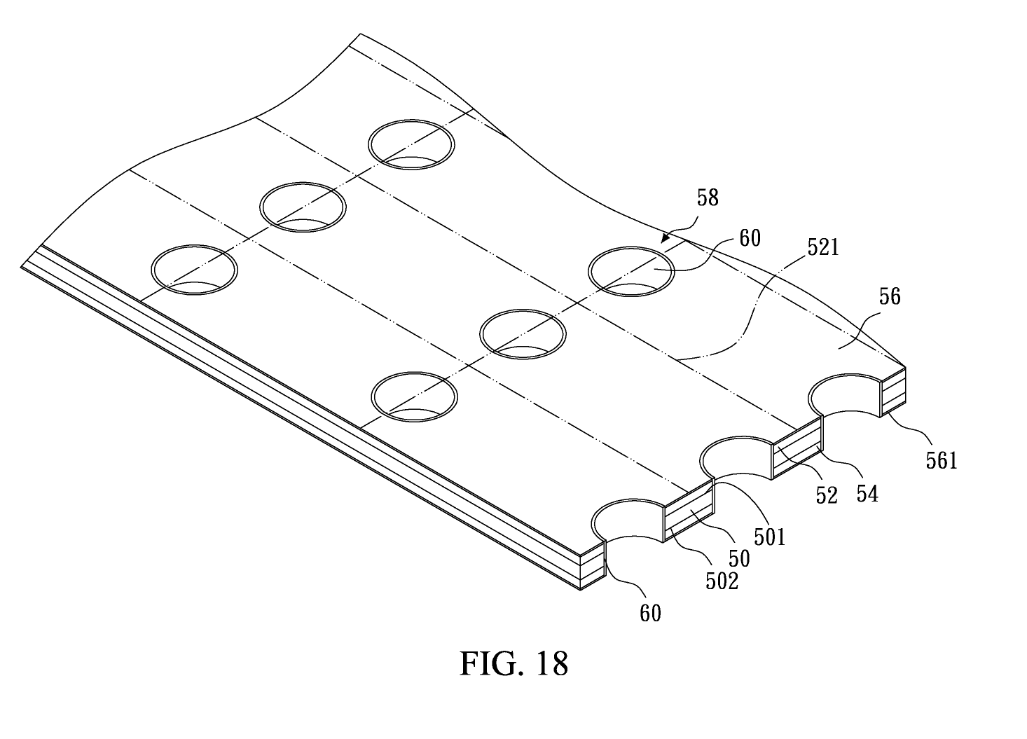

Referring to FIG. 18, a connecting metal layer 60 is formed in the through holes 58 to electrically connect the resistor layer 52 and the first metal layer 54. In this embodiment, the connecting metal layer 60 is a chemical metal layer, such as chemical Cu layer, and is formed by a chemical plating process.

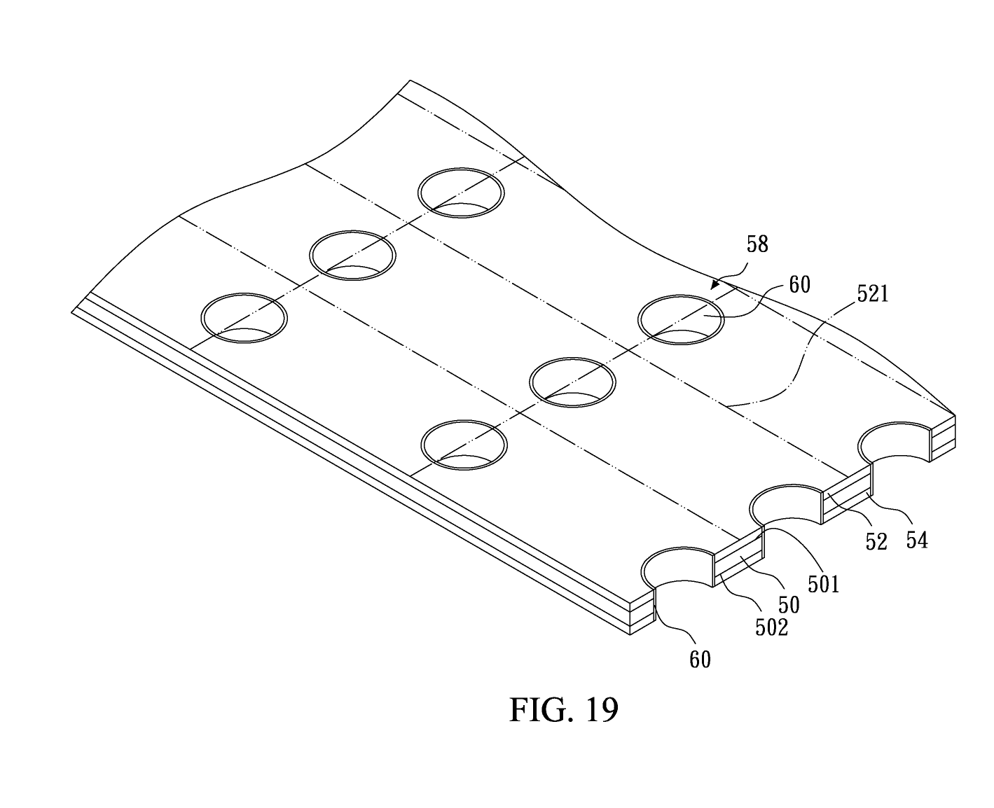

Referring to FIG. 19, the adhesive layer 56 and the second photoresist layer 561 are removed to expose the entire resistor layer 52 and the first metal layer 54.

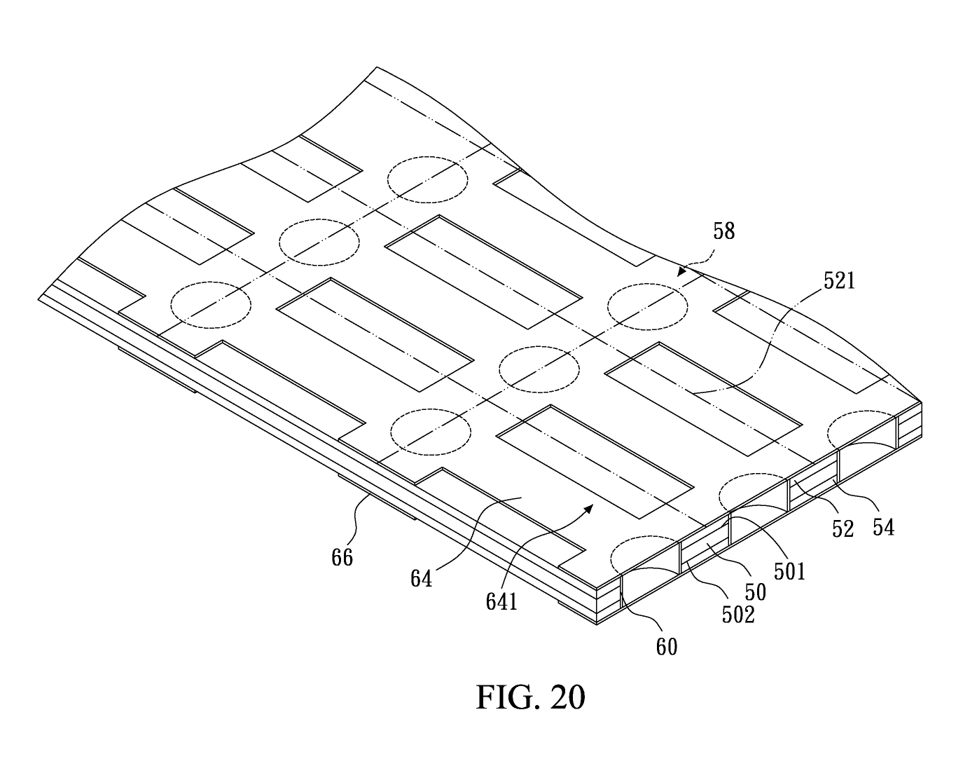

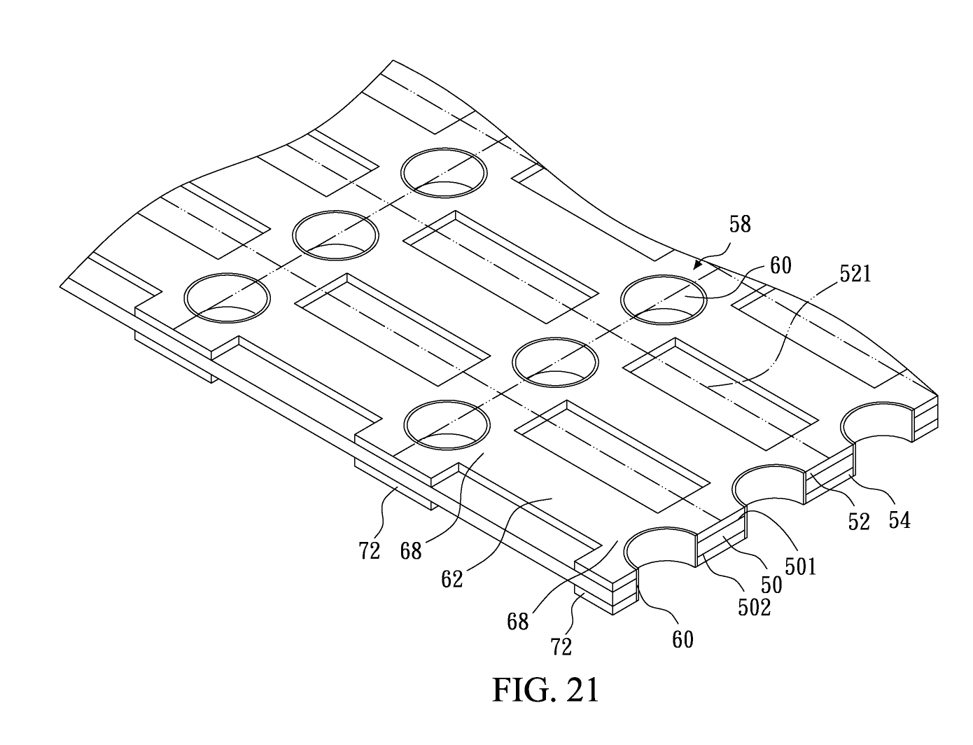

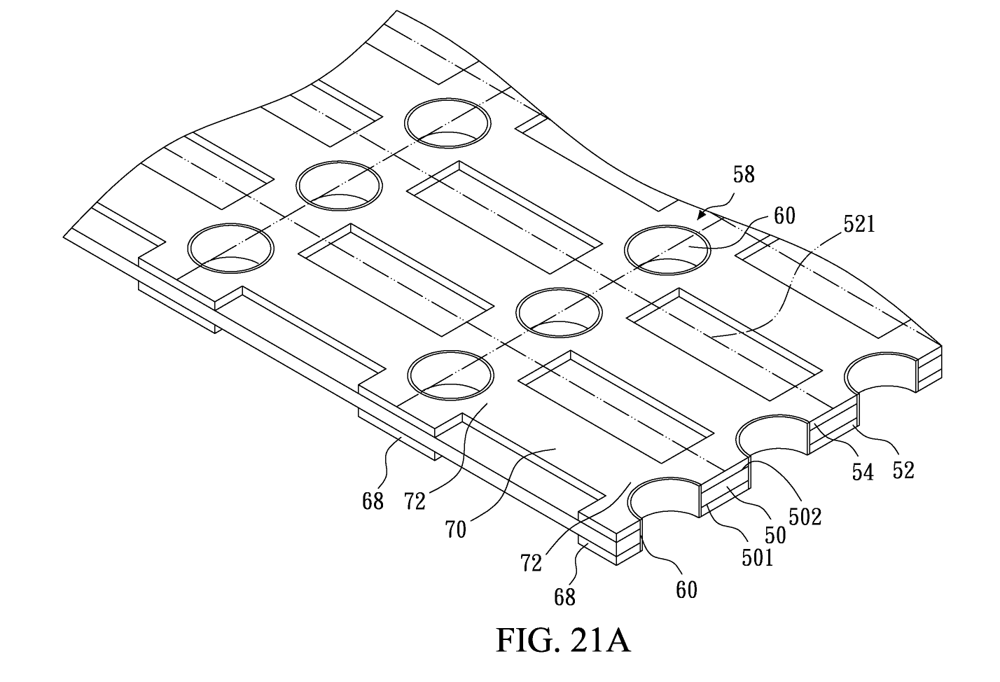

Referring to FIG. 20, FIG. 21 and FIG. 21A, wherein FIG. 21A is a perspective bottom view of FIG. 21. The resistor layer 52 and the first metal layer 54 are patterned. In this embodiment, the patterning process is described as follows. Firstly, referring to FIG. 20, a third photoresist layer 64 is formed on the resistor layer 52, and a fourth photoresist layer 66 is formed on the first metal layer 54. Then, after exposure and development, a third pattern 641 is formed on the third photoresist layer 64, and a fourth pattern (not shown) is formed on the fourth photoresist layer 66. The third pattern 641 and the fourth pattern are a plurality of openings corresponding to each other. The positions of the openings do not correspond to the through holes 58, that is, the openings do not pass through the through holes 58.

Then, referring to FIG. 21 and FIG. 21A, a part of the resistor layer 52 is removed by etching according to the third pattern 641 to expose a part of the first surface 501 of the substrate 50, and a plurality of first resistor bodies 62 and a plurality of back electrodes 68 are formed. Every two back electrodes 68 are located on two sides of each first resistor body 62, and the position of each back electrode 68 corresponds to one through holes 58. A part of the first metal layer 54 is removed by etching according to the fourth pattern to expose a part of the second surface 502 of the substrate 50, and a plurality of second resistor bodies 70 and a plurality of front electrodes 72 are formed. Every two front electrodes 72 are located on two sides of each second resistor body 70, and the position of each front electrode 72 corresponds to one through hole 58. Afterwards, the third photoresist layer 64 and the fourth photoresist layer 66 are removed.

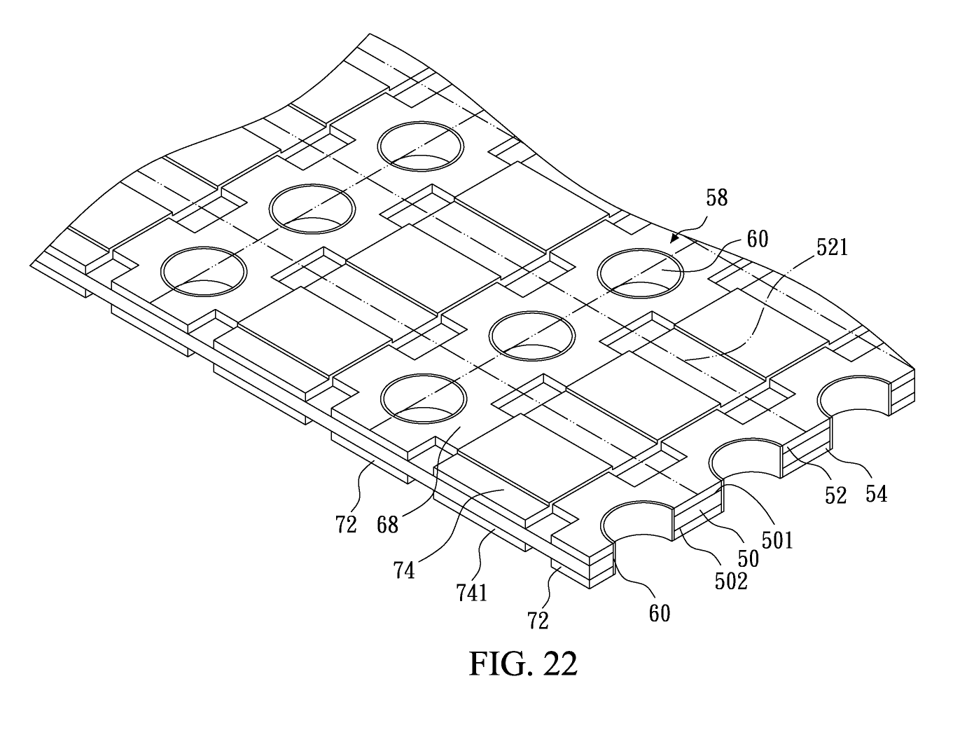

Referring to FIG. 22, a plurality of first non-conductive material layers 74 are formed to cover the first resistor bodies 62 and a part of the first surface 501 of the substrate 50. The first non-conductive material layers 74 are parallel to each other and do not cover the through holes 58. A plurality of second non-conductive material layers 741 are formed to cover the second resistor bodies 70 and a part of the second surface 502 of the substrate 50. The second non-conductive material layers 741 are parallel to each other and do not cover the through holes 58.

In this embodiment, the material of the first non-conductive material layers 74 and the second non-conductive material layers 741 is a dry film or a wet film, and positions thereof correspond to each other.

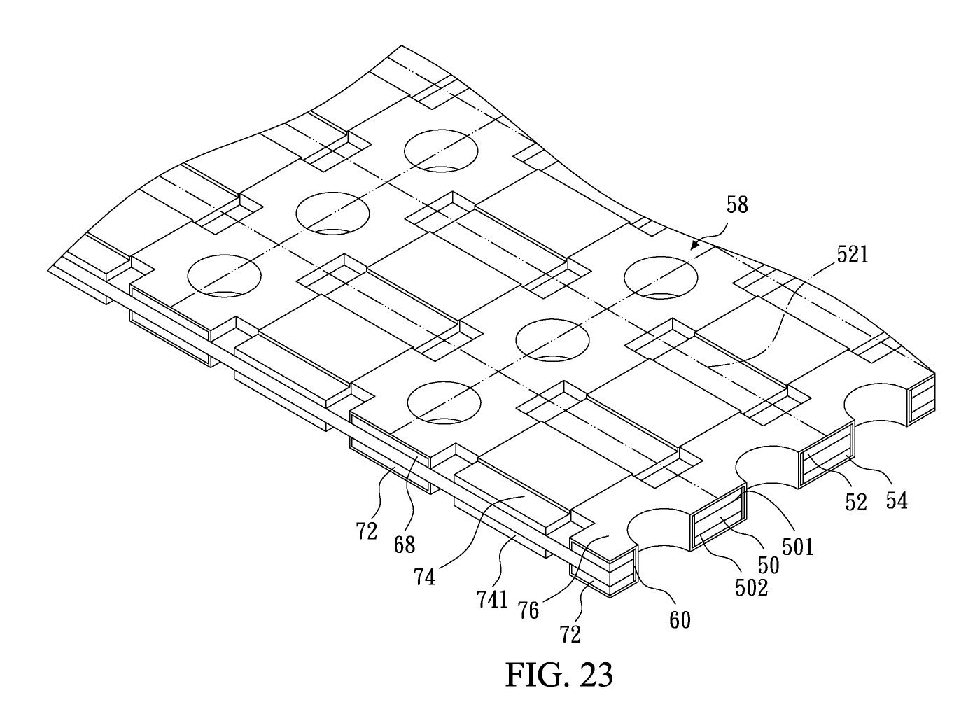

Referring to FIG. 23, a plurality of second metal layers 76 are formed on the connecting metal layer 60, a part of the resistor layer 52 that is not covered by the first non-conductive material layers 74 (that is, the back electrodes 68) and a part of the first metal layer 54 that is not covered by the second non-conductive material layers 741 (that is, the front electrodes 72). In this embodiment, the second metal layer 76 is a Cu layer, and is formed by electroplating. The second metal layer 76 extends to a side edge of the back electrodes 68, and contacts the first surface 501 of the substrate 50. The second metal layer 76 extends to a side edge of the front electrodes 72, and contacts the second surface 502 of the substrate 50.

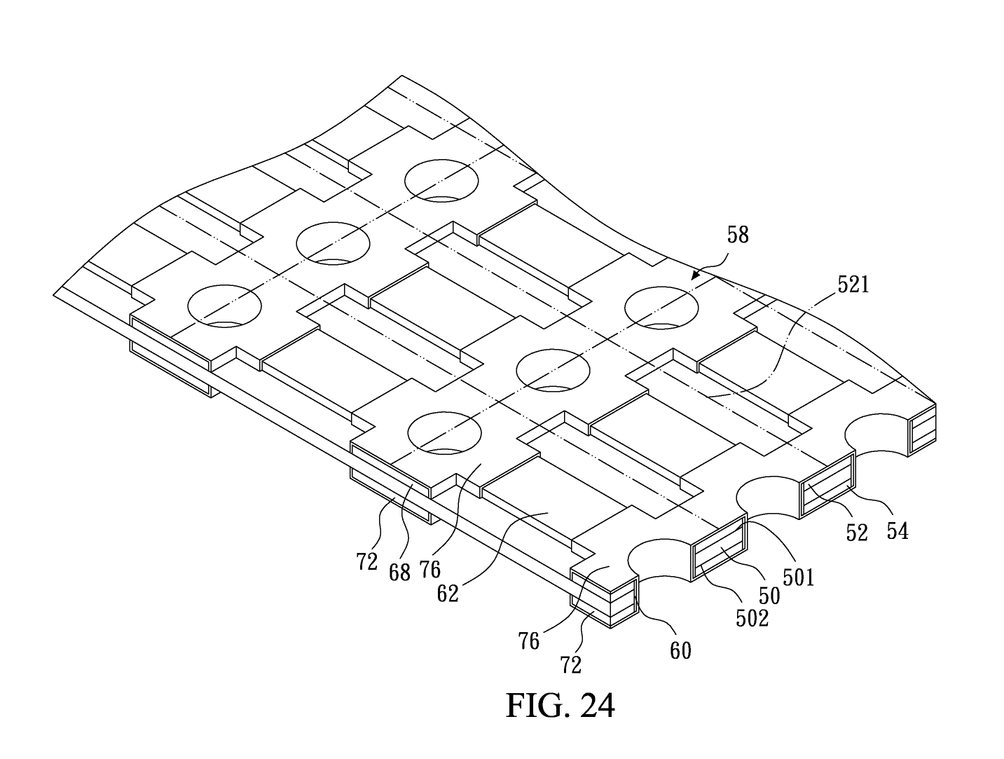

Referring to FIG. 24, the first non-conductive material layers 74 are removed to expose the first resistor bodies 62 and a part of the first surface 501 of the substrate 50. The second non-conductive material layers 741 are removed to expose the second resistor bodies 70 and a part of the second surface 502 of the substrate 50.

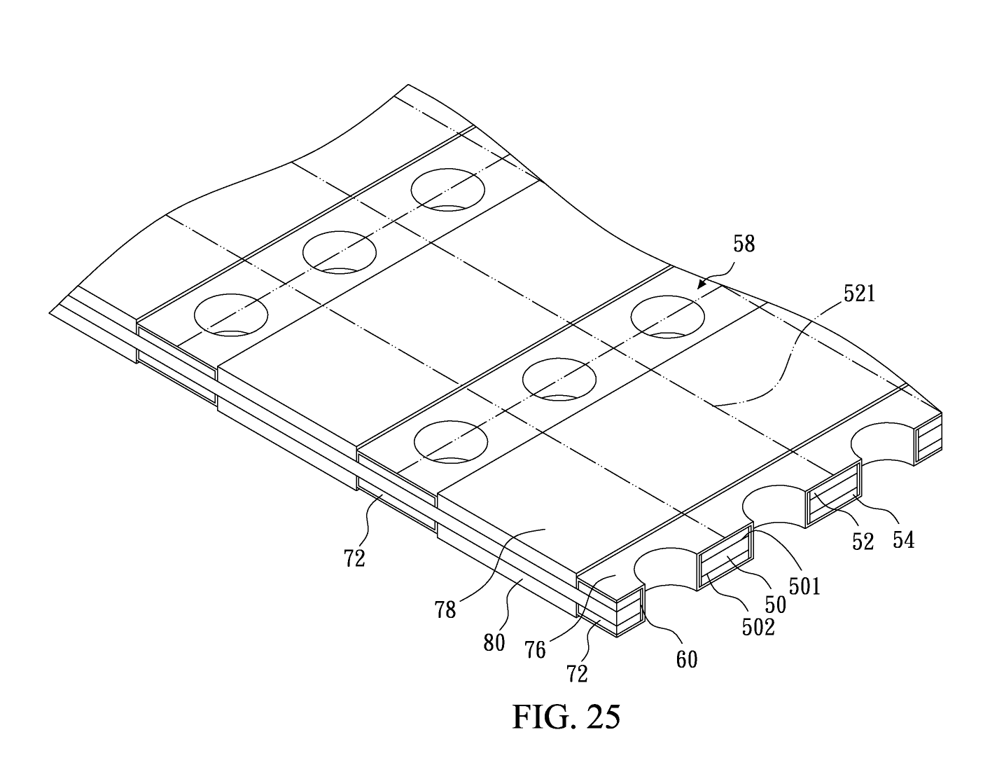

Referring to FIG. 25, a plurality of first protecting layers 78 are formed to protect the first resistor bodies 62, and a plurality of second protecting layers 80 are formed to protect the second resistor bodies 70. In this embodiment, the material of the first protecting layers 78 is a solder resist ink, such as epoxy, and the material of the second protecting layers 80 is a solder resist ink, such as epoxy. The first protecting layers 78 cover the first resistor bodies 62 and a part of the first surface 501 of the substrate 50. The first protecting layers 78 do not cover the through holes 58. The second protecting layers 80 cover the second resistor bodies 70 and a part of the second surface 502 of the substrate 50. The second protecting layers 80 do not cover the through holes 58.

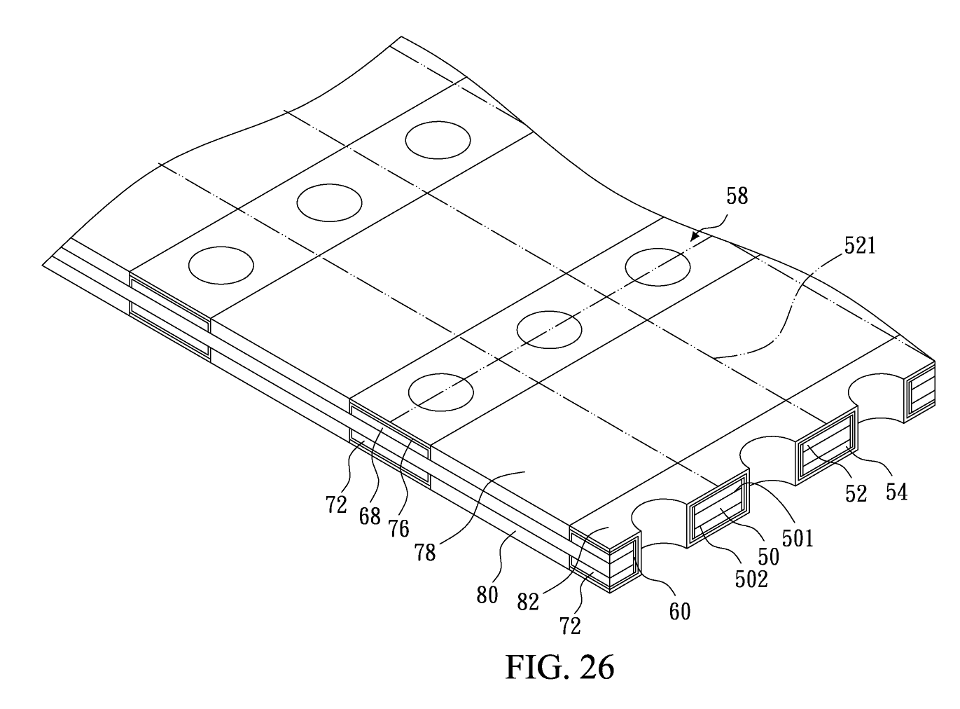

Referring to FIG. 26, a plurality of third metal layers 82 are formed on a part of the second metal layer 76 that is not covered by the first protecting layers 78 and the second protecting layers 80. In this embodiment, the third metal layer 82 is formed by electroplating, and the material is Ni, Sn, or Au. Preferably, if the material of the third metal layer 82 is Ni, an Au or Sn layer may be electroplated thereon. In other embodiments, the third metal layer 82 fills up the through holes 58.

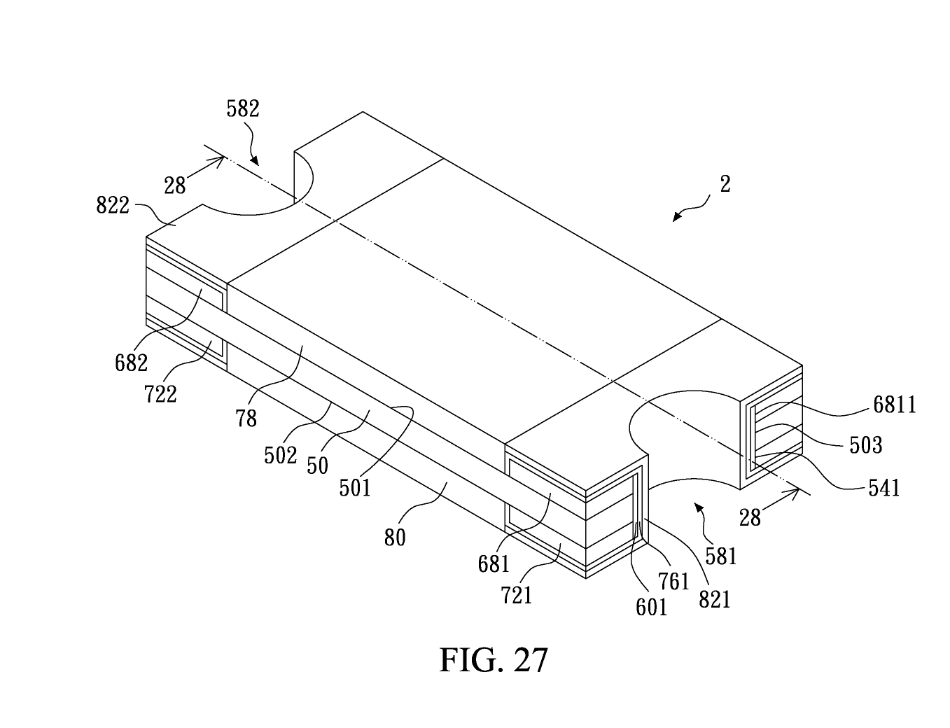

Finally, a singulation process is proceeded along the cutting lines 521 to form a plurality of chip resistors 2, as shown in FIG. 27. A part of the cutting lines 521 pass through the through holes 58.

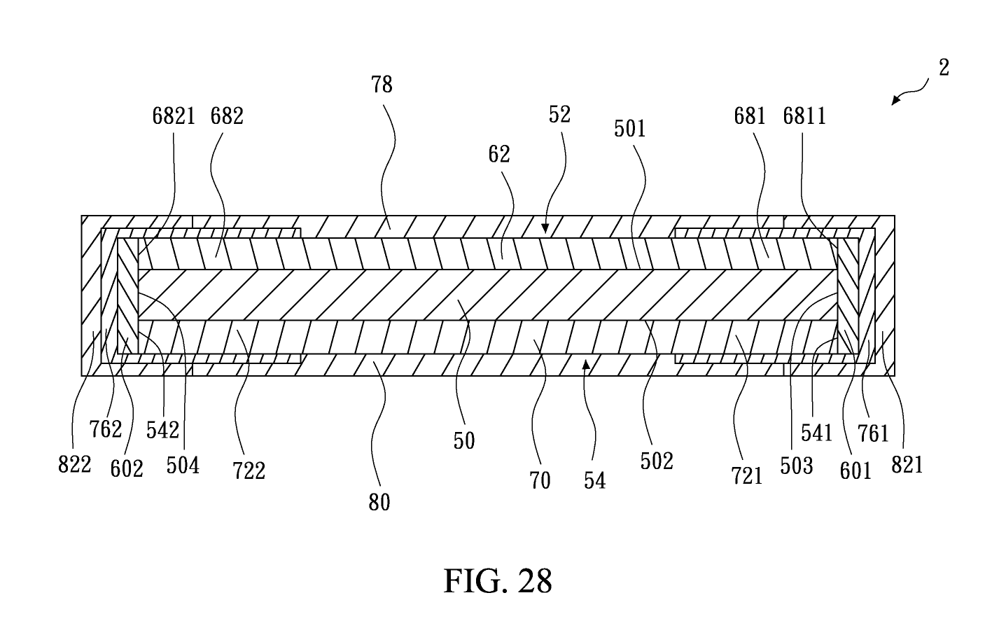

FIG. 27 and FIG. 28 are schematic perspective and cross-sectional views of a chip resistor according to a second embodiment of the present invention respectively. The chip resistor 2 includes a substrate 50, a resistor layer 52, a first metal layer 54, a connecting metal layer and a first protecting layer 78.

The substrate 50 has a first surface 501, a second surface 502, a substrate right opening 503, and a substrate left opening 504. In this embodiment, the substrate 50 is an organic substrate, and preferably is an organic laminate substrate.

The resistor layer 52 is located on the first surface 501 of the substrate 50, and has a first resistor body 62, a right back electrode 681 and a left back electrode 682. The right back electrode 681 and the left back electrode 682 are respectively located on two sides of the first resistor body 62. The right back electrode 681 has a right back electrode opening 6811, and the left back electrode 682 has a left back electrode opening 6821. In this embodiment, the resistor layer 52 is a Cu—Ni alloy foil or a Cu—Mn alloy foil. Preferably, an adhesive layer (not shown) is further formed between the resistor layer 52 and the substrate 50. The right back electrode 681 and the left back electrode 682 are formed by proceeding the singulation process on the back electrodes 68 (FIG. 21).

The first metal layer 54 is located on the second surface 502 of the substrate 50, and has a first right opening 541 and a first left opening 542. The substrate right opening 503, the right back electrode opening 6811 and the first right opening 541 form a right penetrating groove 581, and the substrate left opening 504, the left back electrode opening 6821 and the first left opening 542 form a left penetrating groove 582. In this embodiment, the first metal layer 54 is a Cu—Ni alloy foil or a Cu—Mn alloy foil, and is the same as the resistor layer 52. Preferably, an adhesive layer (not shown) is further formed between the first metal layer 54 and the substrate 50. The first metal layer 54 includes a second resistor body 70, a right front electrode 721, and a left front electrode 722. The right front electrode 721 and the left front electrode 722 are not connected, and are spaced apart to each other. The right front electrode 721 and the left front electrode 722 are formed by proceeding the singulation process on the front electrodes 72 (FIG. 21A).

The connecting metal layer includes a connecting metal right part 601 and a connecting metal left part 602. The connecting metal right part 601 is located in the right penetrating groove 581 and electrically connects the right back electrode 681 and the right front electrode 721. The connecting metal left part 602 is located in the left penetrating groove 582 and electrically connects the left back electrode 682 and the left front electrode 722. In this embodiment, the connecting metal layer is a chemical metal layer, such as chemical Cu layer. The connecting metal right part 601 and the connecting metal left part 602 are formed by proceeding the singulation process on the connecting metal layer 60 (FIG. 26).

The first protecting layer 78 covers the first resistor body 62. In this embodiment, the material of the first protecting layers 78 is a solder resist ink, such as epoxy. The first protecting layer 78 covers the first resistor body 62 and a part of the first surface 501 of the substrate 50.

Preferably, the chip resistor 2 further includes a second metal layer right part 761, a second metal layer left part 762, a second protecting layer 80, a third metal layer right part 821 and a third metal layer left part 822.

The material of the second metal layer right part 761 and the second metal layer left part 762 is Cu. The second metal layer right part 761 is located on the connecting metal right part 601, extends to the side edge of the right back electrode 681, and contacts the first surface 501 of the substrate 50. The second metal layer right part 761 extends to the side edge of the right front electrode 721, and contacts the second surface 502 of the substrate 50.

The second metal layer left part 762 is located on the connecting metal left part 602, extends to the side edge of the left back electrode 682, and contacts the first surface 501 of the substrate 50. The second metal layer left part 762 extends to the side edge of the left front electrode 722, and contacts the second surface 502 of the substrate 50.

The second protecting layer 80 covers the second resistor body 70. In this embodiment, the material of the second protecting layer 80 is a solder resist ink, such as epoxy. The second protecting layer 80 covers the second resistor body 70 and a part of the second surface 502 of the substrate 50.

The third metal layer right part 821 is located on the second metal layer right part 761, and the third metal layer left part 822 is located on the second metal layer left part 762. In this embodiment, the material of the third metal layer right part 821 and the third metal layer left part 822 is Ni, Sn or Au. Preferably, if the material of the third metal layer right part 821 and the third metal layer left part 822 is Ni, an Au or Sn layer may be electroplated thereon.

In this embodiment, the chip resistor 2 has two penetrating grooves (that is, the right penetrating groove 581 and the left penetrating groove 582). However, in other embodiments, the chip resistor 2 may have more than four penetrating grooves, that is, one side has more than two penetrating grooves. The penetrating groove on the same side may be conducted or not conducted.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A method for manufacturing a chip resistor, comprising:
(a) providing a substrate and a resistor layer, wherein the substrate has a first surface and a second surface;
(b) attaching the resistor layer to the first surface of the substrate;
(c) forming a first metal layer on the second surface of the substrate;
(d) forming a plurality of through holes to penetrate the first metal layer, the substrate, and the resistor layer;
(e) forming a connecting metal layer in the through holes to electrically connect the resistor layer and the first metal layer;
(f) patterning the resistor layer to form a plurality of first resistor bodies;
(g) forming a plurality of first protecting layers to protect the first resistor bodies; and
(h) proceeding a singulation process along a plurality of cutting lines to form a plurality of chip resistors, wherein a part of the cutting lines pass through the through holes.

2. The method according to claim 1, wherein the substrate is an organic laminate substrate, the resistor layer is a Cu—Ni alloy foil or a Cu—Mn alloy foil, and the first metal layer is a Cu foil.

3. The method according to claim 1, wherein in step (b), the resistor layer is a sheet material and is attached to the first surface of the substrate by lamination; and in step (c), the first metal layer is a sheet material and is formed on the second surface of the substrate by lamination.

4. The method according to claim 1, wherein after step (c), the method further comprises a step of forming an adhesive layer to cover the resistor layer; and after step (e), the method further comprises a step of removing the adhesive layer.

5. The method according to claim 1, wherein step (f) further comprises a step of forming a plurality of back electrodes, wherein every two back electrodes are located on two sides of each first resistor body.

6. The method according to claim 1, wherein in step (e), the connecting metal layer is further formed on the first metal layer; the step (f) further comprises a step of patterning the connecting metal layer and the to first metal layer to respectively form a plurality of heat dissipation mechanisms and a plurality of front electrodes, wherein the heat dissipation mechanisms are located on the front electrodes.

7. The method according to claim 1, wherein after step (f), the method further comprises the steps of:
(f1) forming a plurality of first non-conductive material layers to cover the first resistor bodies, wherein the first non-conductive material layers do not cover the through holes;
(f2) forming a plurality of second metal layers on the connecting metal layer and a part of the resistor layer that is not covered by the first non-conductive material layers; and
(f3) removing the first non-conductive material layers.

8. The method according to claim 7, wherein after step (g), the method further comprises a step of:
(g1) forming a plurality of second protecting layers to cover a part of the second metal layers and a part of the second surface of the substrate, wherein the second protecting layers do not cover the through holes.

9. The method according to claim 8, wherein after step (g1), the method further comprises a step of:
(g2) forming a plurality of third metal layers on a part of the second metal layer that is not covered by the first protecting layers and the second protecting layers.

10. The method according to claim 1, wherein step (g) comprises a step of forming the first protecting layers to cover the first resistor bodies and a part of the first surface of the substrate, wherein the first protecting layers do not cover the through holes.

11. The method according to claim 1, wherein the substrate is an organic laminate substrate, the resistor layer is a Cu—Ni alloy foil or a Cu—Mn alloy foil, and the first metal layer is a Cu—Ni alloy foil or a Cu—Mn alloy foil.

12. The method according to claim 11, wherein after step (c), the method further comprises a step of forming an adhesive layer to cover the resistor layer and forming a second photoresist layer to cover the first metal layer; and after step (e), the method further comprises a step of removing the adhesive layer and the second photoresist layer.

13. The method according to claim 11, wherein step (f) comprises a step of patterning the resistor layer to form a plurality of first resistor bodies and a plurality of back electrodes, and patterning the first metal layer to form a plurality of second resistor bodies and a plurality of front electrodes, wherein every two back electrodes are located on two sides of each first resistor body, and every two front electrodes are located on two sides of each second resistor body.

14. The method according to claim 13, wherein after step (f), the method further comprises the steps of:
(f1) forming a plurality of first non-conductive material layers to cover the first resistor bodies, wherein the first non-conductive material layers do not cover the through holes;
(f2) forming a plurality of second non-conductive material layers to cover the second resistor bodies, wherein the second non-conductive material layers do not cover the through holes;
(f3) forming a plurality of second metal layers on the connecting metal layer, a part of the resistor layer that is not covered by the first non-conductive material layers, and a part of the first metal layer that is not covered by the second non-conductive materials; and
(f4) removing the first non-conductive material layers and the second non-conductive material layers.

15. The method according to claim 14, wherein after step (g), the method further comprises a step of:
(g1) forming a plurality of second protecting layers to protect the second resistor bodies.

16. The method according to claim 15, wherein after step (g1), the method further comprises a step of:
(g2) forming a plurality of third metal layers on a part of the second metal layer that is not covered by the first protecting layers and the second protecting layers.

17. A chip resistor, comprising:
a substrate, having a first surface, a second surface, a substrate right opening and a substrate left opening;
a resistor layer, located on the first surface of the substrate and having a first resistor body, a right back electrode and a left back electrode, wherein the right back electrode and the left back electrode are respectively located on two sides of the first resistor body, the right back electrode has a right back electrode opening, and the left back electrode has a left back electrode opening;
a first metal layer, located on the second surface of the substrate and having a first right opening and a first left opening, wherein the substrate right opening, the right back electrode opening and the first right opening form a right penetrating groove, and the substrate left opening, the left back electrode opening and the first left opening form a left penetrating groove;
a connecting metal layer, having a connecting metal right part and a connecting metal left part, wherein the connecting metal right part and the connecting metal left part are not connected, the connecting metal right part is located in the right penetrating groove and electrically connects the right back electrode and the first metal layer, and the connecting metal left part is located in the left penetrating groove and electrically connects the left back electrode and the first metal layer; and
a first protecting layer, covering the first resistor body.

18. The chip resistor according to claim 17, wherein the substrate is an organic laminate substrate, the resistor layer is a Cu—Ni alloy foil or a Cu—Mn alloy foil, and the first metal layer is a Cu foil.

19. The chip resistor according to claim 18, wherein the first metal layer comprises a right front electrode and a left front electrode, the right front electrode and the left front electrode are not connected, the connecting metal layer comprises a right heat dissipation mechanism and a left heat dissipation mechanism, the right heat dissipation mechanism is located on the right front electrode, and the left heat dissipation mechanism is located on the left front electrode.

20. The chip resistor according to claim 19, further comprising a second protecting layer located on the second surface of the substrate between the right front electrode and the left front electrode.

21. The chip resistor according to claim 17, wherein the substrate is an organic laminate substrate, the resistor layer is a Cu—Ni alloy foil or a Cu—Mn alloy foil, and the first metal layer is a Cu—Ni alloy foil or a Cu—Mn alloy foil.

22. The chip resistor according to claim 21, wherein the first metal layer has a second resistor body, a right front electrode, and a left front electrode, and the right front electrode and the left front electrode are respectively located on two sides of the second resistor body.

23. The chip resistor according to claim 22, further comprising a second protecting layer covering the second resistor body.

24. The chip resistor according to claim 17, further comprising a second metal layer right part and a second metal layer left part, the second metal layer right part is located on the connecting metal right part, and the second metal layer left part is located on the connecting metal left part.

25. The chip resistor according to claim 24, further comprising a third metal layer right part and a third metal layer left part, the third metal layer right part is located on the second metal layer right part, and the third metal layer left part is located on the second metal layer left part.

26. The chip resistor according to claim 25, wherein the material of the second metal layer right part and the second metal layer left part is Cu, and the material of the third metal layer right part and the third metal layer left part is Ni, Au or Sn.
